(19) United States
(12) Patent Application Publication
(10) Pub. No.: US 2025/0393206 A1
(43) Pub. Date: Dec. 25, 2025

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Yonggang Yang, Wuhan (CN); Zhenguo Wu, Wuhan (CN)

(21) Appl. No.: 18/776,716

(22) Filed: Jul. 18, 2024

Related U.S. Application Data
(63) Continuation of application No. PCT/CN2024/101319, filed on Jun. 25, 2024.

(51) Int. Cl. H10B 43/27; H01L 23/00; H01L 25/065; H01L 25/18; H10B 41/27; H10B 80/00

(52) U.S. Cl. CPC H10B 43/27; H01L 24/08; H01L 25/0657; H01L 25/18; H10B 41/27; H10B 80/00; H01L 2224/08145; H01L 2924/1431; H01L 2924/14511

(57) ABSTRACT

In certain aspects, a memory device includes a stack structure and contact structures. The stack structure includes alternating first layers and first dielectric layers. The first layers in a first portion of the stack structure include second dielectric layers. The first layers in a second portion of the stack structure include conductive layers. The contact structures extend into the first portion of the stack structure in a first direction and connect to corresponding conductive layers from the conductive layers, respectively. The contact structures are divided into one or more groups based on contact depths of the contact structures in the first direction. The one or more groups include a first group including at least a first subset of the contact structures. The first subset of the contact structures in the first group include a first set of contact shoulders located in a first stack pair.

### CROSS-REFERENCE TO RELATED APPLICATIONS

This application is a continuation of International Application No. PCT/CN2024/101319, filed on Jun. 25, 2024, which is hereby incorporated by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, a memory device includes a stack structure and contact structures. The stack structure includes alternating first layers and first dielectric layers. The first layers in a first portion of the stack structure include second dielectric layers, and the first layers in a second portion adjacent to the first portion of the stack structure include conductive layers. The contact structures extend into the first portion of the stack structure in a first direction and connect to corresponding conductive layers from the conductive layers, respectively. The contact structures are divided into one or more groups based on contact depths of the contact structures in the first direction. The one or more groups include a first group including at least a first subset of the contact structures associated with a first subset of the contact depths in a first depth range. The first subset of the contact structures in the first group include a first set of contact shoulders located in a first stack pair, and the first stack pair includes a first one of the first dielectric layers and a first one of the second dielectric layers.

In some implementations, the first subset of the contact structures in the first group include a first contact structure. The first contact structure includes a vertical contact member and a lateral contact member connecting to the vertical contact member. The vertical contact member extends in the first direction, and the lateral contact member connects to one of the corresponding conductive layers.

In some implementations, the vertical contact member includes a first vertical-contact segment, a first contact shoulder from the first set of contact shoulders, and a second vertical-contact segment. The first contact shoulder connects to the first vertical-contact segment and the second vertical-contact segment.

In some implementations, in a second direction perpendicular to the first direction, a size of an end of the first vertical-contact segment which connects to the first contact shoulder is greater than a size of an end of the second vertical-contact segment which also connects to the first contact shoulder.

In some implementations, the vertical contact member of the first contact structure further includes a second contact shoulder located within the first depth range. The second contact shoulder connects to the second vertical-contact segment, and a depth of the second contact shoulder in the first direction is greater than a depth of the first contact shoulder in the first direction.

In some implementations, the vertical contact member further includes a third vertical-contact segment. The second contact shoulder connects to the second vertical-contact segment and the third vertical-contact segment.

In some implementations, the first vertical-contact segment has a bowing shape in a cross-sectional view in a plane determined by the first direction and a second direction perpendicular to the first direction.

In some implementations, the first vertical-contact segment has a first end connected to the first contact shoulder and a second end away from the first contact shoulder. In the second direction, a size of the first end of the first vertical-contact segment and a size of the second end of the first vertical-contact segment are smaller than a size of the first vertical-contact segment between the first end and the second end in the second direction.

In some implementations, the first contact structure further includes a spacer surrounding the vertical contact member, a filler surrounded by the vertical contact member, and a contact pad covering the filler and connected to the vertical contact member.

In some implementations, the depth of the second contact shoulder in the first direction is a distance from the contact pad to the second contact shoulder in the first direction. The depth of the first contact shoulder in the first direction is a distance from the contact pad to the first contact shoulder in the first direction.

In some implementations, the spacer includes a first spacer segment, a spacer shoulder, and a second spacer segment. The spacer shoulder connects to the first spacer segment and the second spacer segment, and is located in the first stack pair.

In some implementations, the first spacer segment has a bowing shape in a cross-sectional view in a plane determined by the first direction and a second direction perpendicular to the first direction.

In some implementations, the one or more groups further include a second group including a second subset of the contact structures associated with a second subset of the contact depths in a second depth range. The second depth range is different from the first depth range.

In some implementations, the second subset of the contact structures in the second group include a second set of contact shoulders located in a second stack pair including a second one of the first dielectric layers and a second one of the second dielectric layers. The second stack pair is different from the first stack pair.

In some implementations, the second portion of the stack structure includes a first sub-portion and a second sub-portion separated from the first sub-portion, and the first portion of the stack structure is between and connects to the first sub-portion and the second sub-portion.

In some implementations, the first portion of the stack structure includes a third sub-portion and a fourth sub-portion separated from the third sub-portion, and the second portion of the stack structure is between and connects to the third sub-portion and the fourth sub-portion.

In some implementations, the memory device further includes a peripheral circuit connected to the contact structures.

In some implementations, the peripheral circuit includes a device layer including transistors, and the contact structures connect to the device layer.

In some implementations, the one or more groups further include: a third group including a third subset of the contact structures associated with a third subset of the contact depths in a third depth range; and a fourth group including a fourth subset of the contact structures associated with a fourth subset of the contact depths in a fourth depth range. A first contact depth of a first contact structure in the first group is greater than a second contact depth of a second contact structure in the second group. The second contact depth of the second contact structure in the second group is greater than a third contact depth of a third contact structure in the third group. The third contact depth of the third contact structure in the third group is greater than a fourth contact depth of a fourth contact structure in the fourth group. The first contact structure is disposed followed by the second contact structure, the third contact structure, and the fourth contact structure subsequently in a second direction perpendicular to the first direction.

In another aspect, a memory device includes a stack structure, a first group of contact structures, and a second group of contact structures. The stack structure includes alternating first layers and first dielectric layers. The first layers in a first portion of the stack structure include second dielectric layers, and the first layers in a second portion adjacent to the first portion of the stack structure include conductive layers. The first group of contact structures extend into the first portion of the stack structure in a first direction and connect to a first subset of the conductive layers, respectively. The first group of contact structures have first contact depths in a first depth range, respectively, and include a first set of contact shoulders located in a first stack pair. The second group of contact structures extend into the first portion of the stack structure in the first direction and connect to a second subset of the conductive layers, respectively. The second group of contact structures have second contact depths in a second depth range, respectively, and include a second set of contact shoulders located in a second stack pair different from the first stack pair.

In some implementations, the first stack pair includes a first one of the first dielectric layers and a first one of the second dielectric layers. The second stack pair includes a second one of the first dielectric layers and a second one of the second dielectric layers.

In some implementations, the first group of contact structures include a first contact structure. The first contact structure includes a vertical contact member and a lateral contact member connecting to the vertical contact member. The vertical contact member extends in the first direction, and the lateral contact member connects to one of the first subset of the conductive layers.

In some implementations, the vertical contact member includes a first vertical-contact segment, a first contact shoulder from the first set of contact shoulders, and a second vertical-contact segment. The first contact shoulder connects to the first vertical-contact segment and the second vertical-contact segment.

In some implementations, in a second direction perpendicular to the first direction, a size of an end of the first vertical-contact segment connected to the first contact shoulder is greater than a size of an end of the second vertical-contact segment connected to the first contact shoulder.

In some implementations, the vertical contact member of the first contact structure further includes a second contact shoulder located within the first depth range. The second contact shoulder connects to the second vertical-contact segment, and a depth of the second contact shoulder in the first direction is greater than a depth of the first contact shoulder in the first direction.

In some implementations, the vertical contact member further includes a third vertical-contact segment. The second contact shoulder connects to the second vertical-contact segment and the third vertical-contact segment.

In some implementations, the first vertical-contact segment has a bowing shape in a cross-sectional view in a plane determined by the first direction and a second direction perpendicular to the first direction.

In some implementations, the first vertical-contact segment has a first end connected to the first contact shoulder and a second end away from the first contact shoulder. In the second direction, a size of the first end of the first vertical-contact segment and a size of the second end of the first vertical-contact segment are smaller than a size of the first vertical-contact segment between the first end and the second end.

In some implementations, the first contact structure further includes a spacer surrounding the vertical contact member, a filler surrounded by the vertical contact member, and a contact pad covering the filler and connected to the vertical contact member.

In some implementations, the depth of the second contact shoulder in the first direction is a distance from the contact pad to the second contact shoulder in the first direction. The depth of the first contact shoulder in the first direction is a distance from the contact pad to the first contact shoulder in the first direction.

In some implementations, the spacer includes a first spacer segment, a spacer shoulder, and a second spacer segment. The spacer shoulder connects to the first spacer segment and the second spacer segment, and is located in the first stack pair.

In some implementations, the first spacer segment has a bowing shape in a cross-sectional view in a plane determined by the first direction and a second direction perpendicular to the first direction.

In some implementations, the second portion of the stack structure includes a first sub-portion and a second sub-portion separated from the first sub-portion, and the first portion of the stack structure is between and connects to the first sub-portion and the second sub-portion.

In some implementations, the first portion of the stack structure includes a third sub-portion and a fourth sub-portion separated from the third sub-portion, and the second portion of the stack structure is between and connects to the third sub-portion and the fourth sub-portion.

In some implementations, the memory device further includes a peripheral circuit connected to the first and second groups of contact structures.

In some implementations, the peripheral circuit includes a device layer including transistors, and the first and second groups of contact structures are connected to the device layer.

In some implementations, the memory device further includes: a third group of contact structures associated with third contact depths in a third depth range; and a fourth group of contact structures associated with fourth contact depths in a fourth depth range. A first contact depth of a first contact structure in the first group is greater than a second contact depth of a second contact structure in the second group. The second contact depth of the second contact structure in the second group is greater than a third contact depth of a third contact structure in the third group. The third contact depth of the third contact structure in the third group is greater than a fourth contact depth of a fourth contact structure in the fourth group. The first contact structure is disposed followed by the second contact structure, the third contact structure, and the fourth contact structure subsequently in a second direction perpendicular to the first direction.

In still another aspect, a method for forming a memory device is disclosed. The method includes forming a stack structure including alternating first dielectric layers and second dielectric layers, and forming contact structures extending into the stack structure in a first direction. The contact structures are divided into one or more groups based on contact depths of the contact structures in the first direction. The one or more groups include a first group including at least a first subset of the contact structures associated with a first subset of the contact depths in a first depth range. The first subset of the contact structures include a first set of contact shoulders located in a first stack pair, and the first stack pair includes a first one of the first dielectric layers and a first one of the second dielectric layers.

In some implementations, forming the contact structures includes forming a first set of contact holes for the first group in the stack structure, and forming the first subset of the contact structures in the first set of contact holes, respectively.

In some implementations, forming the first set of contact holes includes forming a block layer on the stack structure, and etching the block layer and the stack structure with a first mask to form a first set of openings for the first group in the stack structure. The first set of openings have a first depth in the first direction, and bottoms of the first set of openings are in the first stack pair.

In some implementations, forming the first set of contact holes further includes using a second mask to etch the stack structure at one or more first openings from the first set of openings to form one or more second openings extending further into the stack structure.

In some implementations, the first set of contact holes include a first contact hole including a first one of the one or more first openings and a first one of the one or more second openings. A first sidewall shoulder is formed at a bottom of the first one of the one or more first openings.

In some implementations, the stack structure includes a first portion and a second portion adjacent to the first portion. The contact structures extend into the first portion of the stack structure. The method further includes performing a gate line replacement process to replace parts of the second dielectric layers in the second portion of the stack structure with conductive layers. The contact structures extend into the first portion of the stack structure and connect to corresponding conductive layers from the conductive layers, respectively.

In some implementations, the first subset of the contact structures in the first group include a first contact structure including a spacer, a vertical contact member, and a lateral contact member. Forming the first subset of the contact structures in the first set of contact holes, respectively, includes forming the first contact structure in the first contact hole at least by forming the spacer on a sidewall of the first contact hole; and forming the lateral contact member below a bottom of the first contact hole and forming the vertical contact member on a sidewall of the spacer to connect to the lateral contact member. The lateral contact member connects to one of the conductive layers.

In some implementations, the vertical contact member includes a first vertical-contact segment, a first contact shoulder from the first set of contact shoulders, and a second vertical-contact segment. The first contact shoulder connects to the first vertical-contact segment and the second vertical-contact segment.

In some implementations, in a second direction perpendicular to the first direction, a size of an end of the first vertical-contact segment connected to the first contact shoulder is greater than a size of an end of the second vertical-contact segment connected to the first contact shoulder.

In some implementations, the first vertical-contact segment has a bowing shape in a cross-sectional view in a plane determined by the first direction and a second direction perpendicular to the first direction.

In some implementations, the first vertical-contact segment has a first end connected to the first contact shoulder and a second end away from the first contact shoulder. A size of the first end of the first vertical-contact segment in the second direction and a size of the second end of the first vertical-contact segment in the second direction are smaller than a size of the first vertical-contact segment between the first end and the second end in the second direction.

In some implementations, the spacer includes a first spacer segment, a spacer shoulder, and a second spacer segment. The spacer shoulder connects to the first spacer segment and the second spacer segment, and is in the first stack pair.

In some implementations, the spacer shoulder is formed on the first sidewall shoulder, and the first contact shoulder is formed on the spacer shoulder.

In some implementations, the first spacer segment has a bowing shape in a cross-sectional view in a plane determined by the first direction and a second direction perpendicular to the first direction.

In some implementations, the one or more groups further include a second group including a second subset of the contact structures associated with a second subset of the contact depths in a second depth range. The second depth range is different from the first depth range.

In some implementations, forming the contact structures further includes forming a second set of contact holes for the second group in the stack structure, and forming the second subset of the contact structures in the second set of contact holes, respectively.

In some implementations, the second subset of the contact structures in the second group include a second set of contact shoulders located in a second stack pair including a second one of the first dielectric layers and a second one of the second dielectric layers. The second stack pair is different from the first stack pair. Forming the second set of contact holes includes etching the block layer and the stack structure with a third mask to form a second set of openings in the stack structure. The second set of openings have a second depth in the first direction, and bottoms of the second set of openings are in the second stack pair. Forming the second set of contact holes further includes, during formation of the one or more second openings, using the second mask to etch the stack structure at one or more third openings from the second set of openings to form one or more fourth openings extending further into the stack structure.

In some implementations, the second set of contact holes include a second contact hole including a first one of the one or more third openings and a first one of the one or more fourth openings. A second sidewall shoulder is formed at a bottom of the first one of the one or more third openings.

In some implementations, forming the first set of contact holes further includes using a fourth mask to etch the stack structure at a second one of the one or more second openings to form a fifth opening extending further into the stack structure. Forming the second set of contact holes further includes using the fourth mask to etch the stack structure at a second one of the one or more fourth openings to form a sixth opening extending further into the stack structure. The first set of contact holes include a third contact hole including a second one of the one or more first openings corresponding to the second one of the one or more second openings, the second one of the one or more second openings, and the fifth opening. A third sidewall shoulder is formed at a bottom of the second one of the one or more second openings. The second set of contact holes include a fourth contact hole including a second one of the one or more third openings corresponding to the second one of the one or more fourth openings, the second one of the one or more fourth openings, and the sixth opening. A fourth sidewall shoulder is formed at a bottom of the second one of the one or more fourth openings.

In some implementations, the first subset of the contact structures in the first group include a third contact structure formed in the third contact hole. The third contact structure includes a first contact shoulder from the first set of contact shoulders and formed on a first sidewall shoulder. The third contact structure further includes a second contact shoulder formed on the third sidewall shoulder. A depth of the second contact shoulder in the first direction is greater than a depth of the first contact shoulder in the first direction.

In some implementations, the third contact structure further includes a contact pad. The depth of the second contact shoulder in the first direction is a distance from the contact pad to the second contact shoulder in the first direction. The depth of the first contact shoulder in the first direction is a distance from the contact pad to the first contact shoulder in the first direction.

In some implementations, forming the second set of contact holes further includes etching the block layer with a fifth mask to form a set of mask openings, and, during formation of the one or more second openings, using the second mask to etch the stack structure at a mask opening from the set of mask openings to form a seventh opening extending into the stack structure. The second set of contact holes include a fifth contact hole including the seventh opening.

In some implementations, one of the contact structures is formed in a contact hole, the contact hole includes a plurality of openings formed by etching the stack structure with a plurality of etching times, and a total number of contact shoulders formed in the one of the contact structure is equal to a total number of the plurality of etching times minus 1.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a plan view of a 3D memory device having contact structures, according to some aspects of the present disclosure.

FIG. 2A illustrates a cross-sectional side view of a first example implementation of contact structures, according to some aspects of the present disclosure.

FIG. 2B illustrates a cross-sectional side view of a contact structure of FIG. 2A, according to some aspects of the present disclosure.

FIG. 2C illustrates a cross-sectional side view of a second example implementation of contact structures, according to some aspects of the present disclosure.

FIG. 2D illustrates a plan view of an arrangement of contact structures in a memory device, according to some aspects of the present disclosure.

FIG. 2E illustrates contact depths of the contract structures in FIG. 2D, according to some aspects of the present disclosure.

FIG. 3A illustrates cross-sectional side views of a 3D memory device having contact structures, according to some aspects of the present disclosure.

FIG. 3B illustrates enlarged cross-sectional side views of a 3D memory device having contact structures, according to some aspects of the present disclosure.

FIG. 4 illustrates a cross-sectional side view of a 3D memory device including a peripherical circuit, according to some aspects of the present disclosure.

FIGS. 5A-5J illustrate a fabrication process for forming a 3D memory device having contact structures, according to some aspects of the present disclosure.

FIG. 6 is a flowchart of a method for forming a 3D memory device having contact structures, according to some aspects of the present disclosure.

FIGS. 7A-7Q illustrate a fabrication process for forming contact structures in a stack structure, according to some aspects of the present disclosure.

FIG. 8 illustrates different numbers of layers to be etched using different masks, according to some aspects of the present disclosure.

FIG. 9 is a flowchart of another method for forming a 3D memory device having contact structures, according to some aspects of the present disclosure.

FIG. 10 is a flowchart of a method for forming contact structures in a stack structure, according to some aspects of the present disclosure.

FIG. 11 illustrates a block diagram of an exemplary system having a 3D memory device, according to some aspects of the present disclosure.

FIG. 12A illustrates a diagram of an exemplary memory card having a 3D memory device, according to some aspects of the present disclosure.

FIG. 12B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which lateral contact members and/or vertical contacts are formed) and one or more dielectric layers.

In some 3D memory devices, such as 3D NAND memory devices, memory cells for storing data are vertically stacked through a stack structure (e.g., a memory stack) in vertical channel structures. 3D memory devices usually include staircase structures formed on one or more sides (edges), or at the center, of the stacked storage structure for purposes such as word line pick-up/fan-out using word line contacts landed onto different steps/levels of a staircase structure. In some implementations, the word line pick-up/fan-out functions can be achieved without using the staircase structures and word line contacts, so that the manufacturing cost can be reduced and the fabrication process can be simplified. For example, the two structures-staircase structure and word line contact, as well as their separate processes, can be merged into a single contact structure (e.g., a word line pick-up structure) in one process, thereby reducing the manufacturing cost and simplifying the process.

Specifically, contact structures can be formed to extend through alternating first dielectric layers and second dielectric layers in a stack structure of a memory device. The word line pick-up/fan-out functions of the memory device can be achieved by the contact structures. In the fabrication process, a plurality of photoresist masks can be used to etch the alternating first dielectric layers and second dielectric layers to form contact holes for the contact structures, so that the contact structures can be formed in the contact holes, respectively. The contact holes may have different etching depths such that the number of layers etched for each contact hole may be different.

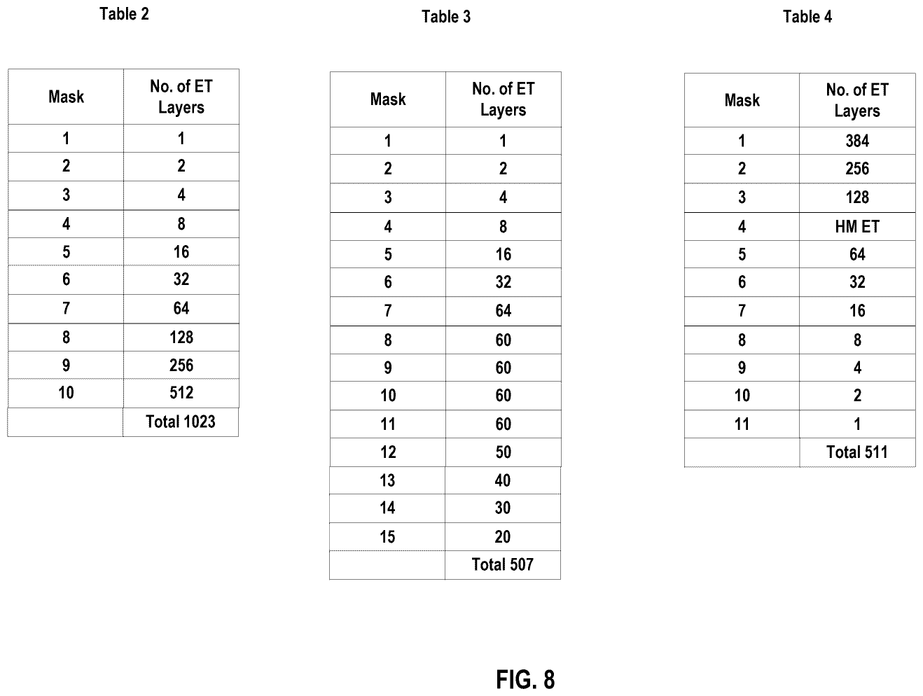

Theoretically, the number of etched layers can be up to 2ⁿ−1 with n masks, as shown in Table 2 of FIG. 8. However, in practice, this theoretical limit cannot be reached, and more masks (e.g., more than n masks) are needed to achieve the etched layers of 2ⁿ−1, as shown in Table 3 of FIG. 8. Thus, the manufacturing cost may increase as the etched layers increase (e.g., due to more masks and more etching times being needed). On the other hand, a contact hole in which a contact structure is formed may be formed by combining multiple openings together, where the multiple openings can be formed by multiple etchings into the stack structure with multiple masks, respectively. A critical dimension (CD) of a contact structure formed in the contact hole is large since multiple etchings are performed to form the contact hole. A large area of the memory device may be occupied by contact structures with large CDs, and the remaining area where channel structures are formed in the memory device is reduced, resulting in a low storage density in the memory device. Additionally, with the increase of the etched layers, under etching or over etching of the layers may occur, leading to etching defects in the memory device.

For example, with reference to Table 3 of FIG. 8, 15 masks may be needed to etch 507 layers. Considering the thickness of each photoresist mask and the development of the photoresist mask, a single etching with a photoresist mask can reach a depth of at most 64 layers in the stack structure. For a contact hole formed by etching 507 layers, 15 masks are used to perform 15 etchings to form 15 openings, respectively, so that the contact hole is formed by combining the 15 openings together. Since 15 masks are used in the etchings, the CD of the contact structure formed thereof can be large. The difference between the profiles of the 15 openings formed by the different etchings can be large. Over etching or under etching of the layers may occur.

To address one or more of the aforementioned issues, the present disclosure introduces a solution which can simplify the etchings of a stack structure in a memory device during the formation of contact holes. The solution disclosed herein can reduce the number of etching times and also the number of masks used in the etchings. As a result, CDs of contact structures formed thereof can be reduced. The fabrication process of the memory device can be simplified, and the manufacturing cost of the memory device can be reduced.

For example, in the solution disclosed herein, the contact structures can be divided into different contact groups based on their respective contact depths. The formation of contact holes for the contact structures can be divided into two steps. Initially, for each contact group, a group of openings can be formed by etching the stack structure using a mask, where the group of openings may have the same depth. Then, different groups of openings having different depths can be formed for the different contact groups using different masks, respectively. Next, one or more additional masks may be used to further etch the stack structure through openings across the different groups of openings, so that contact holes having respective target depths can be formed for the contact structures, respectively. In this way, the number of masks used to form the contact holes can be reduced, and the process of forming the contact holes can be simplified. Etching defects such as over etching or under etching can be reduced or eliminated. CDs of the contact structures formed thereof can also be reduced, so that an area occupied by the contact structures can be reduced, and an area occupied by channel structures can be increased. Thus, the storage density of the memory device can be increased. The manufacturing cost of the memory device can be reduced.

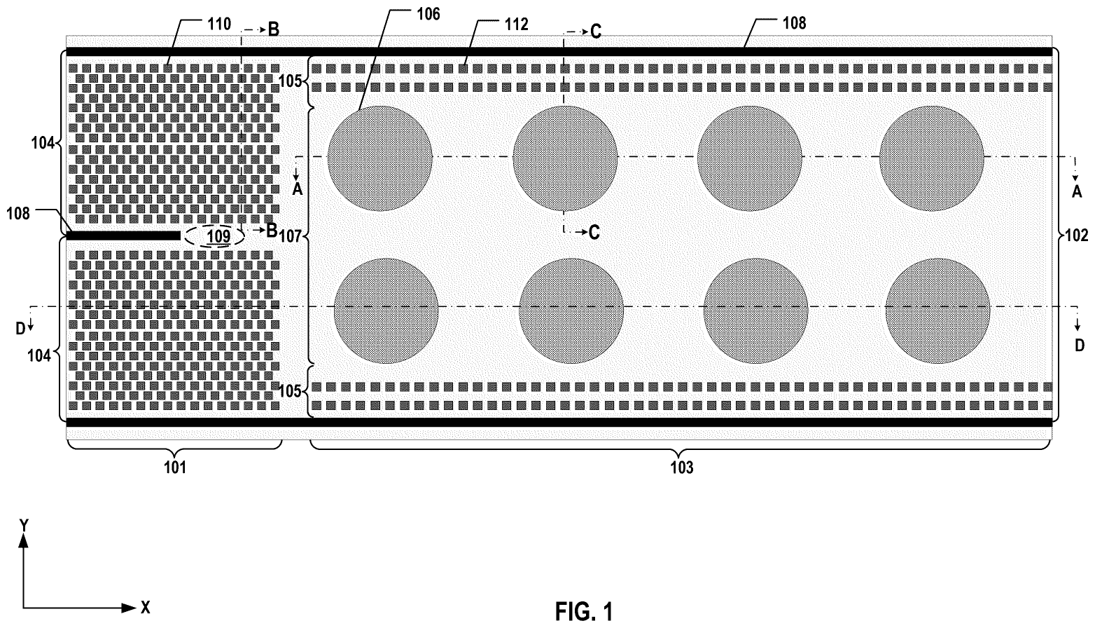

FIG. 1 illustrates a plan view of a 3D memory device 100 having contact structures 106, according to some aspects of the present disclosure. In some implementations, 3D memory device 100 is a NAND Flash memory device in which memory cells are provided in the form of an array of NAND memory strings. It is noted that x and y axes are included in FIG. 1 to illustrate two orthogonal (perpendicular) directions in the wafer plane. The x-direction is the word line direction of 3D memory device 100, and the y-direction is the bit line direction of 3D memory device 100.

As shown in FIG. 1, 3D memory device 100 can include one or more blocks 102 arranged in the y-direction (the bit line direction) separated by parallel slit structures 108, such as gate line slits (GLSs). In some implementations in which 3D memory device 100 is a NAND Flash memory device, each block 102 is the smallest erasable unit of the NAND Flash memory device. Each block 102 can further include multiple fingers 104 in the y-direction separated by some slit structures 108 with “H” cuts 109.

As shown in FIG. 1, 3D memory device 100 can be divided into at least a core array region 101 in which an array of channel structures 110 are formed, as well as a word line pick-up region 103 in which contact structures 106 are formed. Core array region 101 and word line pick-up region 103 are arranged in the x-direction (the word line direction), according to some implementations. It is understood that although one core array region 101 and one word line pick-up region 103 are illustrated in FIG. 1, multiple core array regions 101 and/or multiple word line pick-up regions 103 may be included in 3D memory device 100, for example, one word line pick-up region 103 between two core array regions 101 in the x-direction, in other examples. It is also understood that FIG. 1 only illustrates portions of core array region 101 that are adjacent to word line pick-up region 103.

As described below in more detail, word line pick-up region 103 can include conductive portions 105 and dielectric portions 107 arranged in the y-direction. As shown in FIG. 1, contact structures 106 are disposed in dielectric portion 107, while dummy channel structures 112 are disposed in conductive portion 105 of word line pick-up region 103 to provide mechanical support and/or load balancing, according to some implementations. In some implementations, dummy channel structures 112 can also be disposed in dielectric portion 107 of word line pick-up region 103 as well, for example, between contact structures 106 in the x-direction. In some implementations, dummy channel structures 112 are not disposed in dielectric portion 107 of word line pick-up region 103, i.e., only in conductive portion 105 of word line pick-up region 103. As shown in FIG. 1, each finger 104 of 3D memory device 100 can include one row of contact structures 106 disposed in dielectric portion 107 of word line pick-up region 103. It is understood that the layout and arrangement of contact structures 106, as well as the shape of each contact structure 106, may vary in different examples.

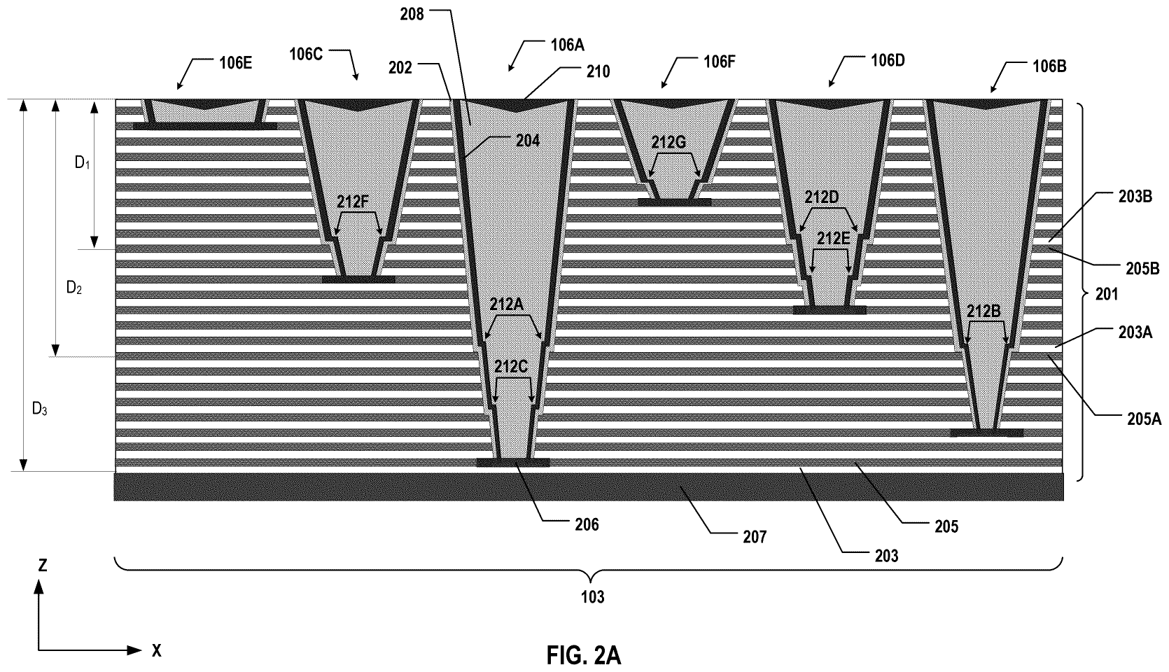

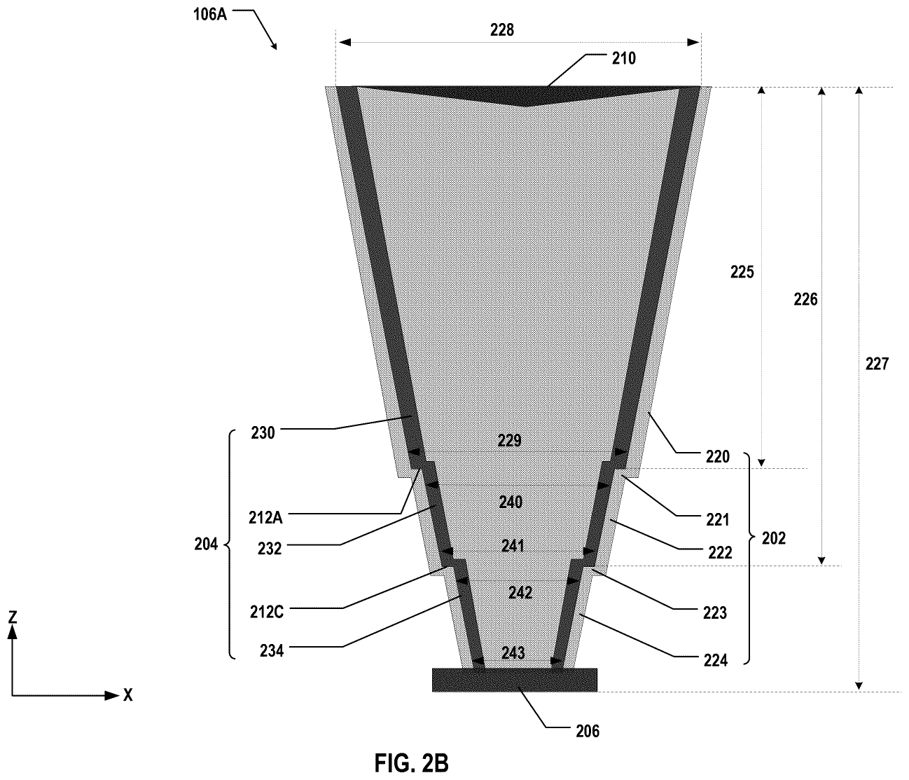

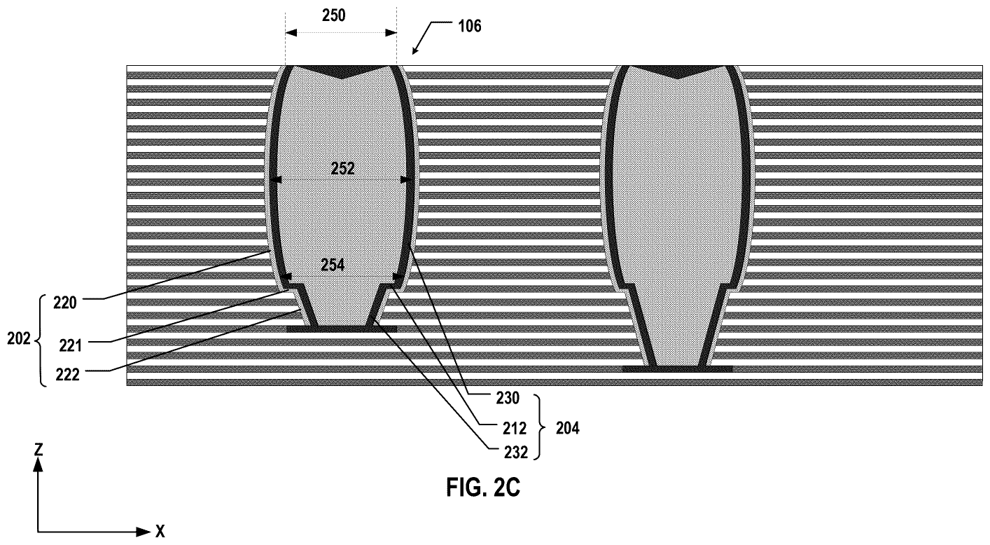

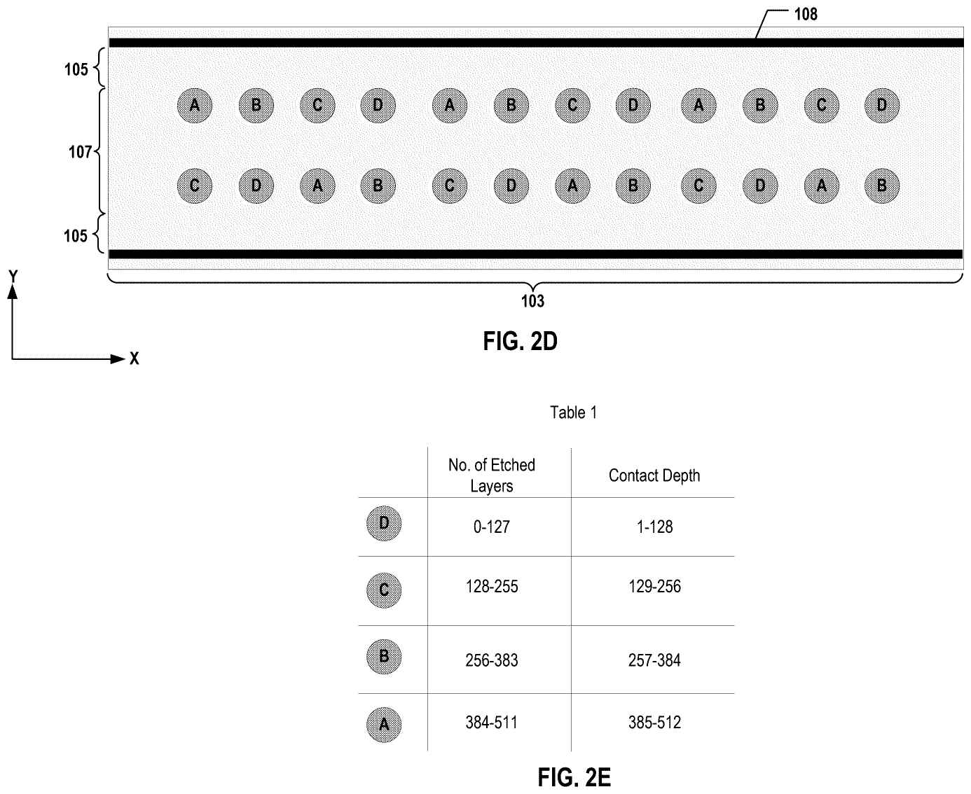

FIG. 2A illustrates a cross-sectional side view of a first example implementation of contact structures 106 in memory device 100, according to some aspects of the present disclosure. The cross-section may be along the AA direction in dielectric portion 107 of word line pick-up region 103 in FIG. 1. FIG. 2B illustrates a cross-sectional side view of a contact structure 106 in FIG. 2A, according to some aspects of the present disclosure. FIGS. 2A and 2B are described below together. Memory device 100 may include a stack structure 201, which may include a first portion and a second portion adjacent to the first portion. The first portion of stack structure 201 may include a part of stack structure 201 in dielectric portion 107 of word line pick-up region 103 shown in FIG. 1. The second portion of stack structure 201 may include another part of stack structure 201 in (i) conductive portion 105 of word line pick-up region 103 and (ii) core array region 101 shown in FIG. 1. Stack structure 201 may include alternating first layers and first dielectric layers 203.

In some implementations, the second portion of stack structure 201 may include: (i) a first sub-portion; and (ii) a second sub-portion which is separated from the first sub-portion. The first portion of stack structure 201 may be located between the first sub-portion and the second sub-portion, and connects to the first sub-portion and the second sub-portion. In some implementations, the first portion of stack structure 201 may include: (i) a third sub-portion; and (ii) a fourth sub-portion which is separated from the third sub-portion. The second portion of stack structure 201 can be located between the third sub-portion and the fourth sub-portion, and connects to the third sub-portion and the fourth sub-portion.

Stack structure 201 can include vertically interleaved first layers and first dielectric layers 203. First layers and first dielectric layers 203 can alternate in the vertical direction (the z-direction). In some implementations, stack structure 201 can include a plurality of material layer pairs stacked vertically in the z-direction, each of which includes a first layer and a first dielectric layer 203. The number of the material layer pairs in stack structure 201 can determine the number of memory cells in memory device 100.

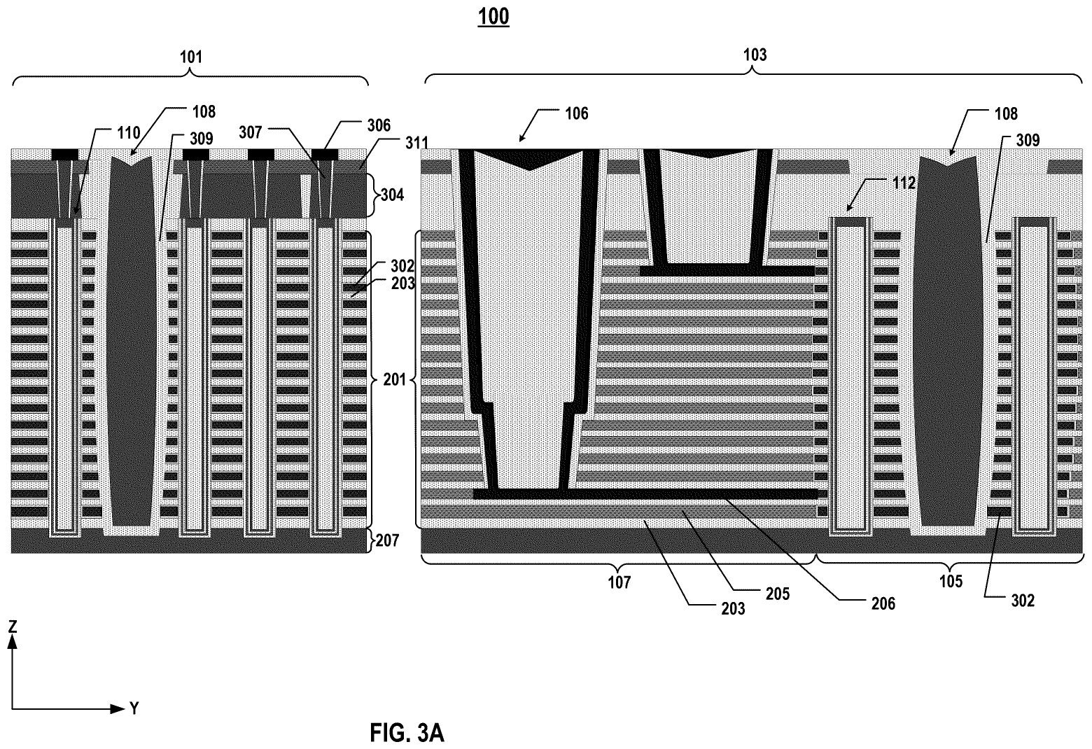

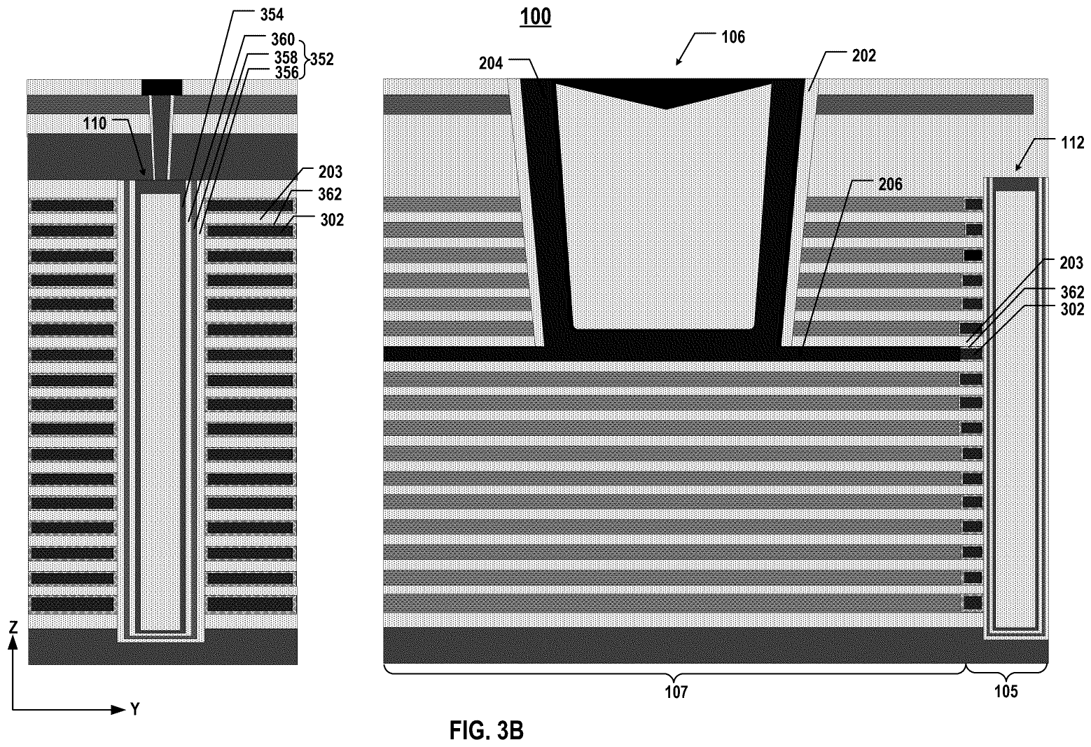

The first layers in the first portion of stack structure 201 may include second dielectric layers 205. That is, the first portion of stack structure 201 may include alternating first dielectric layers 203 and second dielectric layers 205, as shown in FIG. 2A. The first layers in the second portion of stack structure 201 may include conductive layers (e.g., 302 shown in FIG. 3A). That is, the second portion of stack structure 201 may include alternating first dielectric layers 203 and conductive layers 302, as shown in FIG. 3A.

In some implementations, memory device 100 is a NAND Flash memory device, and stack structure 201 is a stacked storage structure through which NAND memory strings are formed. In some implementations, each conductive layer in the second portion of stack structure 201 functions as a gate line of the NAND memory strings (in the forms of channel structures 110) in core array region 101, as well as a word line extending laterally from the gate line and ending in conductive portion 105 of word line pick-up region 103 for word line pick-up/fan-out through contact structures 106. The word lines (i.e., the conductive layers) at different depths/level of the second portion of stack structure 201 each extends laterally in core array region 101 and conductive portion 105 of word line pick-up region 103, but are discontinuous (e.g., being replaced by second dielectric layers 205) in dielectric portion 107 of word line pick-up region 103, according to some implementations.

The conductive layers can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. First dielectric layers 203 or second dielectric layers 205 can include dielectric materials including, but not limited to, silicon oxide, silicon nitride, silicon oxynitride, or any combination thereof. First dielectric layers 203 and second dielectric layers 205 can have different dielectric materials, such as silicon oxide and silicon nitride. In some implementations, the conductive layers include metals, such as tungsten, first dielectric layers 203 include silicon oxide, and second dielectric layers 205 include silicon nitride. For example, first dielectric layers 203 of stack structure 201 may include silicon oxide across core array region 101 and word line pick-up region 103, whereas the first layers of stack structure 201 may include tungsten in core array region 101 and conductive portion 105 of word line pick-up region 103, and may include silicon nitride in dielectric portion 107 of word line pick-up region 103.

In some implementations, stack structure 201 may be formed over a semiconductor layer 207 such as a substrate. The substrate can include silicon (e.g., single crystalline silicon), silicon germanium (SiGe), gallium arsenide (GaAs), germanium (Ge), silicon on insulator (SOI), or any other suitable materials. In some implementations, the substrate includes single crystalline silicon, which is part of the wafer on which memory device 100 is fabricated, either in its native thickness or being thinned. In some implementations, the substrate includes, for example, polysilicon, which is a semiconductor layer replacing the part of the wafer on which memory device 100 is fabricated.

It is noted that x, y, and z axes are included in FIGS. 1 and 2A to illustrate the spatial relationship of the components in memory device 100. Semiconductor layer 207 (e.g., the substrate) of 3D memory device 100 includes two lateral surfaces extending laterally in the x-y plane: a top surface on the front side of the wafer on which stack structure 201 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of 3D memory device 100 is determined relative to semiconductor layer 207 of memory device 100 in the z-direction (the vertical direction perpendicular to the x-y plane) when semiconductor layer 207 is positioned in the lowest plane of memory device 100 in the z-direction. The same notion for describing the spatial relationship is applied throughout the present disclosure.

As shown in FIG. 2A, contact structures 106 extend vertically into stack structure 201 in dielectric portion 107 of word line pick-up region 103 at different depths in the z-direction, according to some implementations. The top surfaces of different contact structures 106 can be flush with one another, while the bottom surfaces of different contact structures 106 can extend to different levels, for example, different second dielectric layers 205 of stack structure 201. For example, contact structures 106A-106F (also referred to as contact structure 106 collectively or individually) may extend into the first portion of stack structure 201 in the z-direction and connect to corresponding conductive layers from the conductive layers, respectively (as shown in FIG. 3A below). Contact structures 106 can be divided into one or more groups based on contact depths of contact structures 106 in the z-direction, as described below in more detail.

In some implementations, the one or more groups may include a first group including at least a first subset of contact structures 106 associated with a first subset of the contact depths in a first depth range. The first subset of contact structures 106 may include a first set of contact shoulders 212 located in a first stack pair. The first stack pair may include a first one of first dielectric layers 203 and a first one of second dielectric layers 205 (e.g., including first dielectric layer 203A and second dielectric layer 205A). The contact depths and the depth range are described below in more detail.

In some implementations, the one or more groups may further include a second group including a second subset of contact structures 106 associated with a second subset of the contact depths in a second depth range. The second depth range is different from the first depth range. The second subset of contact structures 106 may include a second set of contact shoulders 212 located in a second stack pair. The second stack pair is different from the first stack pair, and may include a second one of first dielectric layers 203 and a second one of second dielectric layers 205 (e.g., including first dielectric layer 203B and second dielectric layer 205B). In some implementations, the one or more groups may further include: (i) a third group including a third subset of contact structures 106 associated with a third subset of the contact depths in a third depth range; and (ii) a fourth group including a fourth subset of contact structures 106 associated with a fourth subset of the contact depths in a fourth depth range.

In some implementations, a first contact depth of a first contact structure 106 in the first group is greater than a second contact depth of a second contact structure 106 in the second group. The second contact depth of second contact structure 106 in the second group is greater than a third contact depth of a third contact structure 106 in the third group. The third contact depth of third contact structure 106 in the third group is greater than a fourth contact depth of a fourth contact structure 106 in the fourth group. First contact structure 106 is disposed followed by second contact structure 106, third contact structure 106, and fourth contact structure 106 subsequently in a second direction (e.g., the x-direction) perpendicular to the first direction, as described below with reference to FIG. 2D.

For example, referring to FIG. 2A, the first group may include contact structures 106A and 106B having respective contact depths in a depth range [D₂, D₃], where D₂ and D₃ are positive integers greater than 1 and D₂<D₃. Consistent with some aspects of the present disclosure, a contact depth of a contact structure may be described by the total number of layers in stack structure 201 through which the contact structure extends. For example, a contact structure with the smallest contact depth in the first group may extend through D₂ layers of stack structure 201, and a contact structure with the largest contact depth in the first group may extend through D₃ layers of stack structure 201. As a result, the depth range for the contact structures in the first group is [D₂, D₃].

Contact structure 106A may include a contact shoulder 212A, and contact structure 106B may include a contact shoulder 212B. Contact shoulders 212A and 212B may be in a first stack pair which includes first dielectric layer 203A and second dielectric layer 205A. For example, contact shoulders 212A and 212B may be in the same first dielectric layer 203A. In another example, contact shoulders 212A and 212B may be in the same second dielectric layer 205A. In still another example, contact shoulders 212A and 212B may be located within first dielectric layer 203A and second dielectric layer 205A. Contact structure 106A may also include an additional contact shoulder 212C located within the depth range [D₂, D₃].

With combined reference to FIGS. 2A and 2B, contact structure 106A may have a contact depth 227 in the depth range [D₂, D₃]. Contact structure 106A may include a spacer 202, a vertical contact member 204, a lateral contact member 206, a filler 208, and a contact pad 210. Spacer 202 may surround vertical contact member 204. For example, vertical contact member 204 may be formed on a sidewall of spacer 202. Lateral contact member 206 may connect to vertical contact member 204. Filler 208 may be surrounded by vertical contact member 204. Contact pad 210 may cover filler 208 and connect to vertical contact member 204. Vertical contact member 204 may extend in the z-direction. Lateral contact member 206 may extend in the y-direction to connect to a corresponding conductive layer (e.g., as shown in FIG. 3A below).

Vertical contact member 204 and lateral contact member 206 can include conductive materials including, but not limited to, W, Co, Cu, Al, TiN, polysilicon, doped silicon, silicides, or any combination thereof. Spacer 202 can include dielectric materials including, but not limited to, silicon oxide, silicon nitride, silicon oxynitride, or any combination thereof. In some implementations, vertical contact member 204 and lateral contact member 206 can include TiN/W, and spacer 202 can include silicon oxide. Contact pad 210 can include conductive materials including, but not limited to, W, Co, Cu, Al, TiN, polysilicon, doped silicon, silicides, or any combination thereof. Filler 208 can include dielectric materials including, but not limited to, silicon oxide, silicon nitride, silicon oxynitride, or any combination thereof.

As shown in FIG. 2B, vertical contact member 204 may include a first vertical-contact segment 230, contact shoulder 212A, a second vertical-contact segment 232, contact shoulder 212C, and a third vertical-contact segment 234. Contact shoulder 212 may connect to first vertical-contact segment 230 and second vertical-contact segment 232. Second contact shoulder 212C may connect to second vertical-contact segment 232 and third vertical-contact segment 234.

A depth 226 of contact shoulder 212C in the z-direction can be greater than a depth 225 of contact shoulder 212A in the z-direction. Depth 226 of contact shoulder 212C in the z-direction can be a distance from contact pad 210 to contact shoulder 212C in the z-direction. Depth 225 of contact shoulder 212A in the z-direction can be a distance from contact pad 210 to contact shoulder 212A in the z-direction.

First vertical-contact segment 230 may have a first end connected to contact shoulder 212A and a second end away from contact shoulder 212A. Second vertical-contact segment 232 may have a first end connected to contact shoulder 212A and a second end connected to contact shoulder 212C. Third vertical-contact segment 234 may have a first end connected to contact shoulder 212C and a second end away from contact shoulder 212C. In the x-direction, a size 228 of the second end of first vertical-contact segment 230 is greater than a size 229 of the first end of first vertical-contact segment 230. Size 229 of the first end of first vertical-contact segment 230, which connects to contact shoulder 212A is greater than a size 240 of the first end of second vertical-contact segment 232 which also connects to contact shoulder 212A. Size 240 of the first end of second vertical-contact segment 232 is greater than a size 241 of the second end of second vertical-contact segment 232, which connects to contact shoulder 212C. Size 241 of the second end of second vertical-contact segment 232 is greater than a size 242 of the first end of third vertical-contact segment 234 which also connects to contact shoulder 212C. Size 242 of the first end of third vertical-contact segment 234 is greater than a size 243 of the second end of third vertical-contact segment 234, which is away from contact shoulder 212C.

As shown in FIG. 2B, spacer 202 may include a first spacer segment 220, a spacer shoulder 221, a second spacer segment 222, another spacer shoulder 223, and a third spacer segment 224. Spacer shoulder 221 may connect to first spacer segment 220 and second spacer segment 222, and is located in the same stack pair as contact shoulder 212A. Contact shoulder 212A may be formed on spacer shoulder 221. Spacer shoulder 223 may connect to second spacer segment 222 and third spacer segment 224, and is located in the same stack pair as contact shoulder 212C. Contact shoulder 212C may be formed on spacer shoulder 223.

Referring back to FIG. 2A, the second group may include contact structures 106C and 106D having respective contact depths in a depth range [D₁, D₂−1], where D₁ is a positive integer greater than 1 and D₁<D₂-1. For example, a contact structure with the smallest contact depth in the second group may extend through D₁ layers of stack structure 201, and a contact structure with the largest contact depth in the second group may extend through D₂−1 layers of stack structure 201, so that the depth range for the second group is [D₁, D₂−1].

Contact structure 106C may include a contact shoulder 212F, and contact structure 106D may include a contact shoulder 212D. Contact shoulders 212D and 212F may be in a second stack pair, which includes first dielectric layer 203B and second dielectric layer 205B. For example, contact shoulders 212D and 212F may be in the same first dielectric layer 203B. In another example, contact shoulders 212D and 212F may be in the same second dielectric layer 205B. In still another example, contact shoulders 212D and 212F may be located within first dielectric layer 203B and second dielectric layer 205B. Contact structure 106D may also include an additional contact shoulder 212E located within the depth range [D₁, D₂−1]. A depth of contact shoulder 212E in the z-direction can be greater than a depth of contact shoulder 212D in the z-direction.

The third group may include contact structures 106E and 106F having respective contact depths in a depth range [1, D₁−1]. For example, a contact structure with the smallest contact depth in the third group may extend through one layer of stack structure 201, and a contact structure with the largest contact depth in the third group may extend through D₁−1 layers of stack structure 201, so that the depth range for the third group is [1, D₁−1]. Contact structure 106E may not include any contact shoulder. Contact structure 106F may include a contact shoulder 212G. A depth of contact shoulder 212G is within the depth range [1, D₁−1].

FIG. 2C illustrates a cross-sectional side view of a second example implementation of contact structure 106, according to some aspects of the present disclosure. Contact structure 106 of FIG. 2C may include elements like those described above with reference to FIGS. 2A-2B, and a similar description will not be repeated herein. In some implementations, vertical contact member 204 of contact structure 106 may include a first vertical-contact segment 230, a contact shoulder 212, and a second vertical-contact segment 232. Different from that shown in FIGS. 2A-2B, first vertical-contact segment 230 in FIG. 2C may have a bowing shape in a cross-sectional view in a plane determined by the z-direction and the x-direction. First vertical-contact segment 230 may have a first end connected to contact shoulder 212 and a second end away from contact shoulder 212. A size 250 of the second end of first vertical-contact segment 230 in the x-direction and a size 254 of the first end of first vertical-contact segment 230 in the x-direction are smaller than a size 252 of first vertical-contact segment 230 between the first end and the second end in the x-direction.

In some implementations, spacer 202 may include a first spacer segment 220, a spacer shoulder 221, and a second spacer segment 222. Different from that shown in FIGS. 2A-2B, first spacer segment 220 in FIG. 2C may have a bowing shape in a cross-sectional view in the plane determined by the z-direction and the x-direction. First spacer segment 220 may have a first end connected to spacer shoulder 221 and a second end away from spacer shoulder 221. A size of the first end of first spacer segment 220 in the x-direction and a size of the second end of first spacer segment 220 in the x-direction are smaller than a size of first spacer segment 220 between the first end and the second end in the x-direction.

FIG. 2D illustrates a plan view of an arrangement of contact structures 106 in a memory device, according to some aspects of the present disclosure. The memory device can be memory device 100 of FIG. 1 or any other memory device disclosed herein. In FIG. 2D, contact structures 106 can be classified into four groups, with a first group including contact structures A, a second group including contact structures B, a third group including contact structures C, and a fourth group including contact structures D. The contact structures A, B, C, and D can be arranged in dielectric portion 107 of word line pick-up region 103 alternately. For example, as shown in a first row extending in the x-direction, a contact structure A in the first group is disposed, followed by a contact structure B in the second group, a contact structure C in the third group, and a contact structure D in the fourth group subsequently. Then, following the contact structure D in the fourth group, another contact structure A in the first group is disposed, which is then followed by another contact structure B in the second group, another contact structure C in the third group, and another contact structure D in the fourth group subsequently.

In a second row extending in the x-direction, a contact structure C in the third group is disposed, followed by a contact structure D in the fourth group, a contact structure A in the first group, and a second contact structure B in the second group subsequently. Then, following the contact structure B in the second group, another contact structure C in the third group is disposed, which is then followed by another contact structure D in the fourth group, another contact structure A in the first group, and another contact structure B in second group subsequently. It is contemplated that the contact structures A, B, C, and D can be arranged in dielectric portion 107 in any other manner, which is not limited herein.

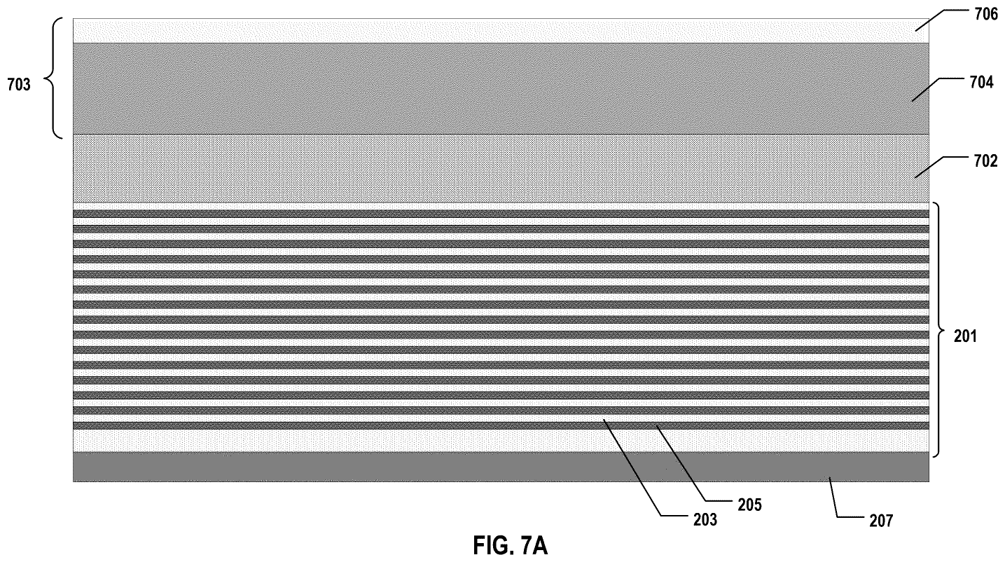

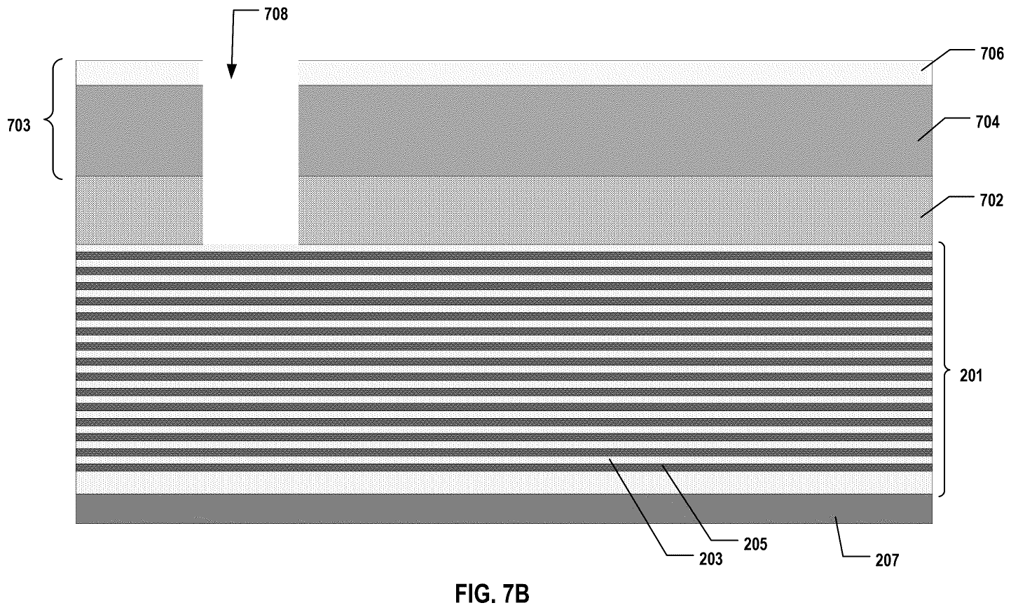

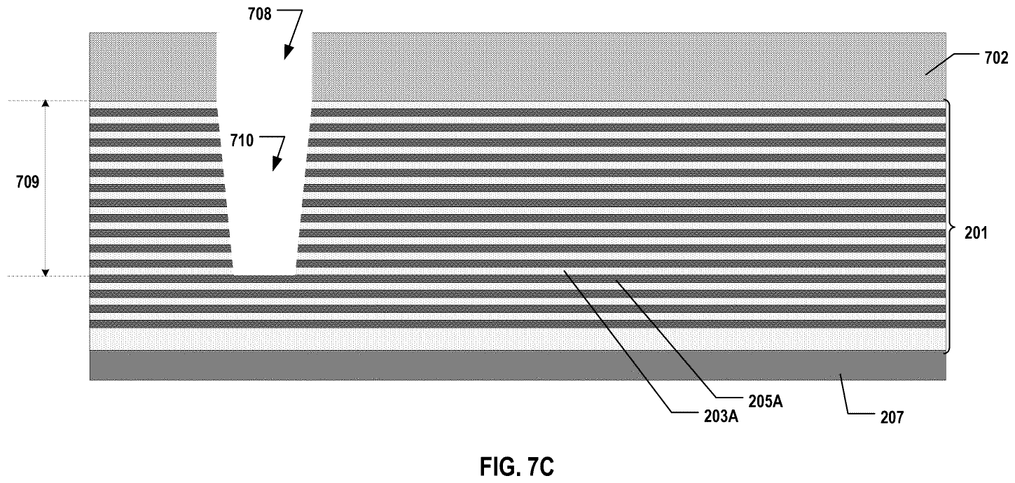

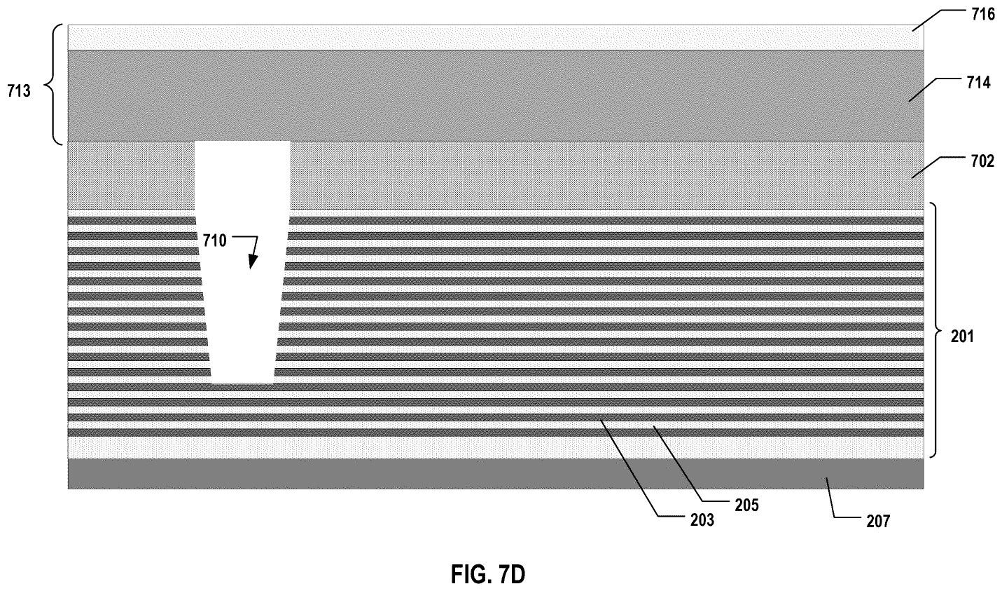

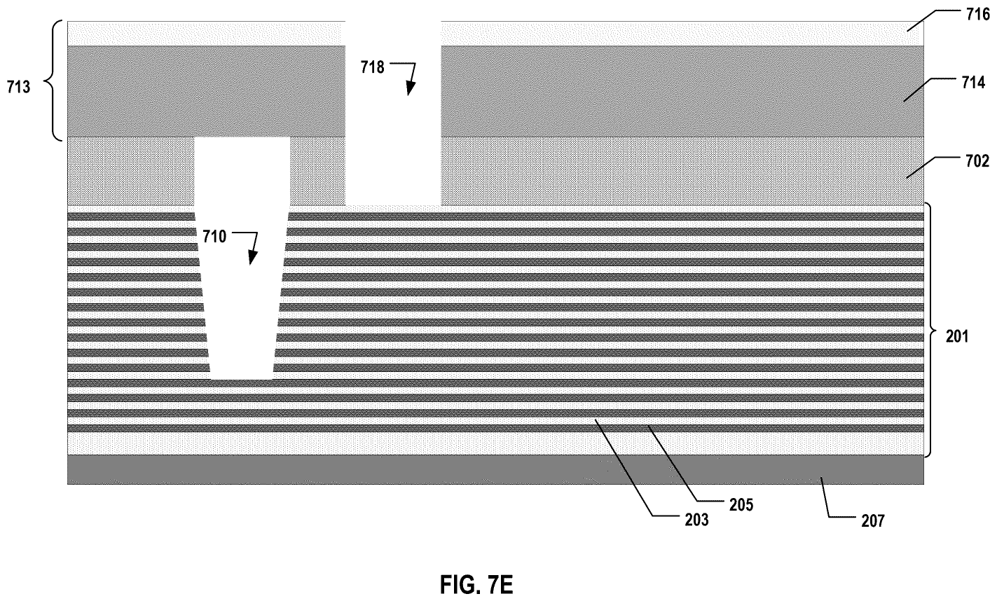

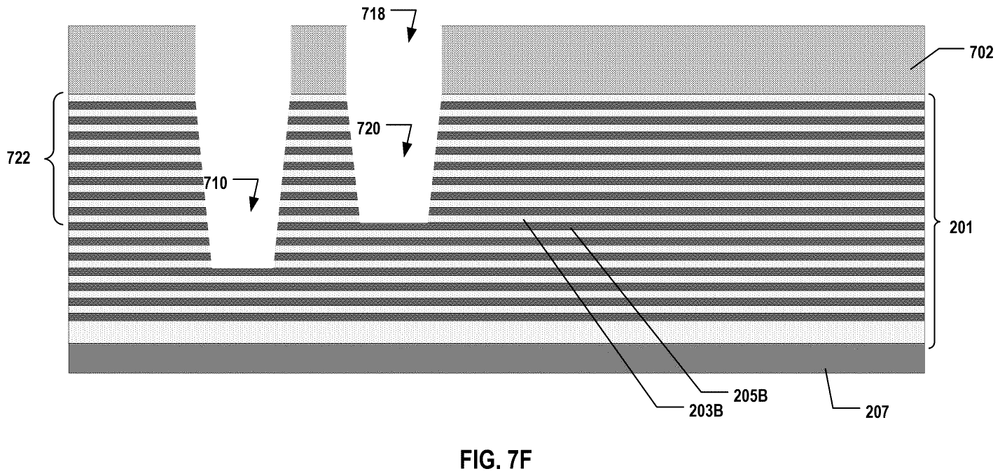

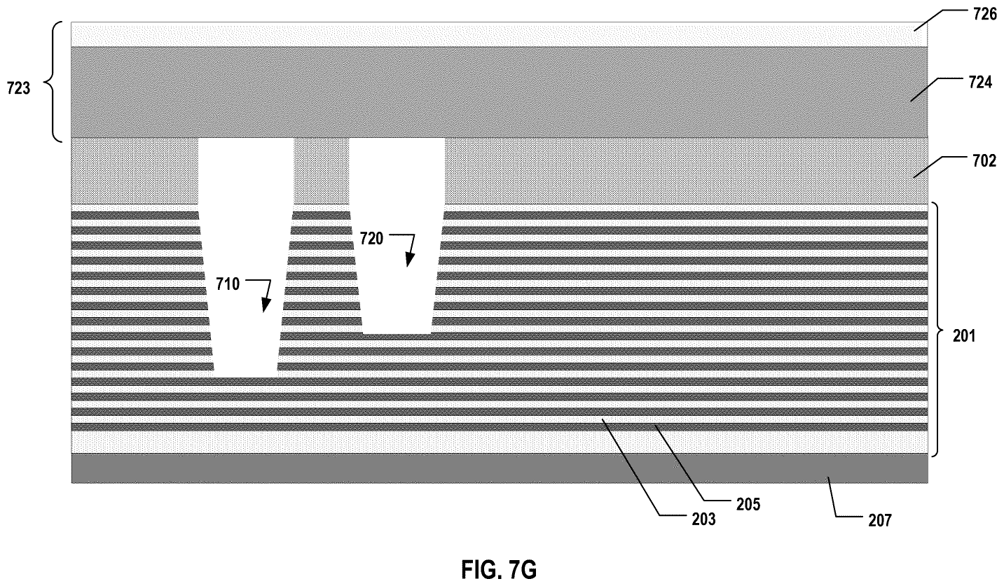

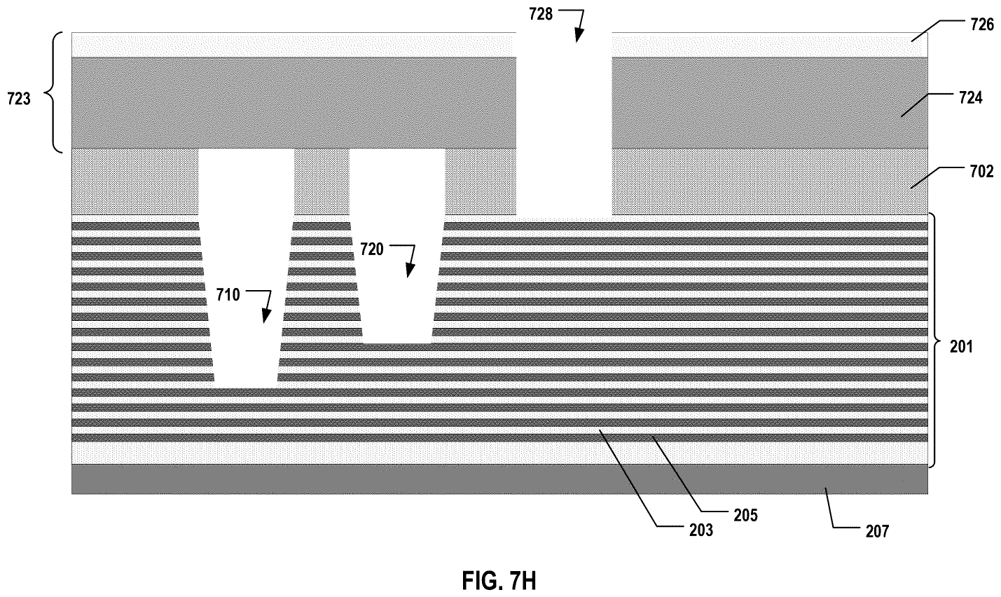

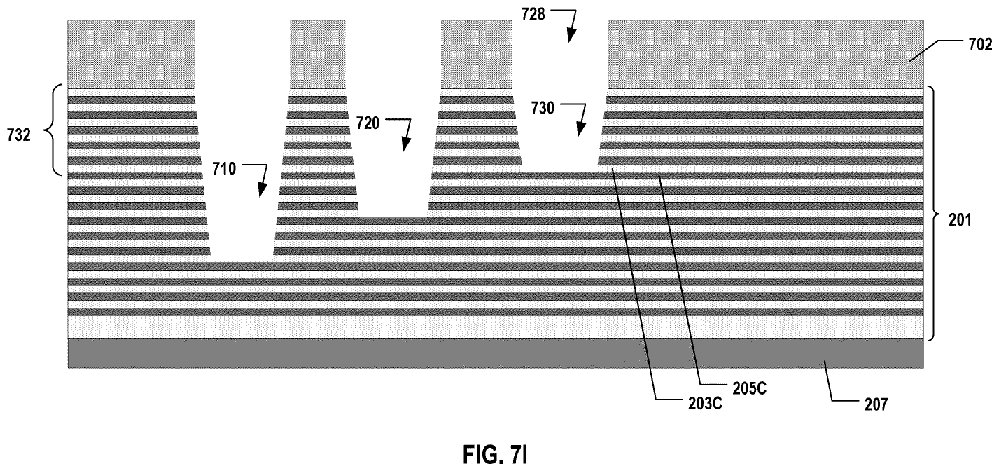

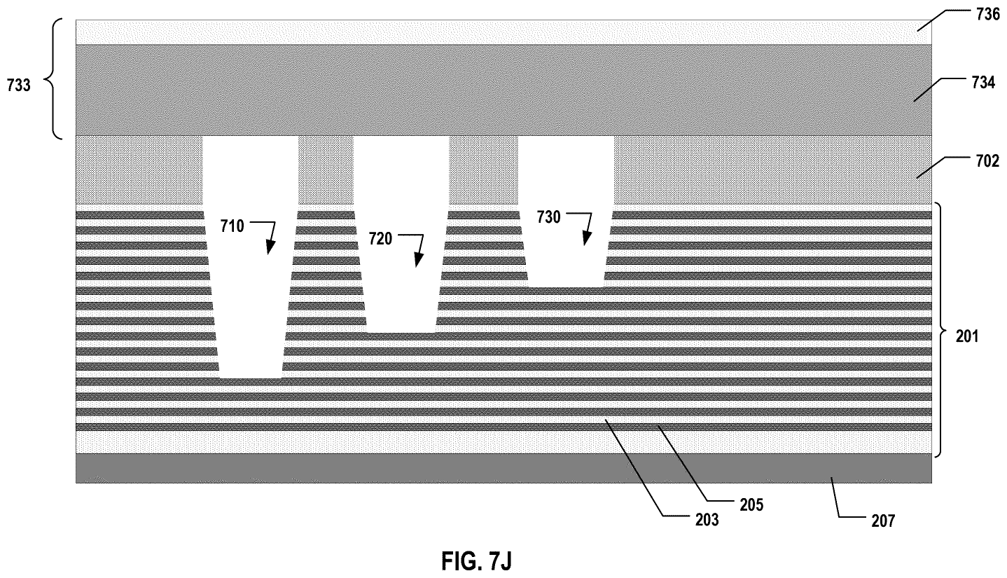

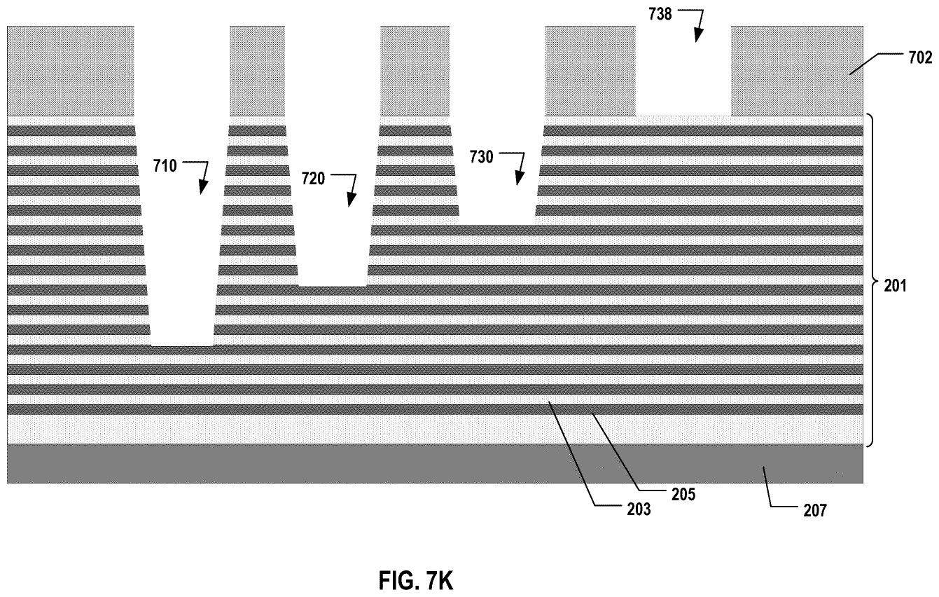

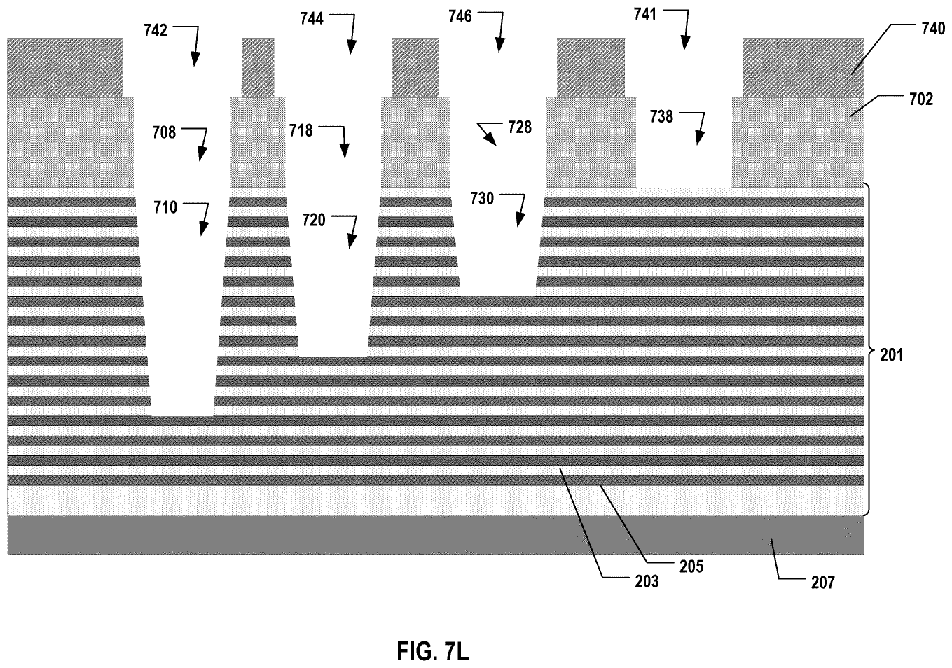

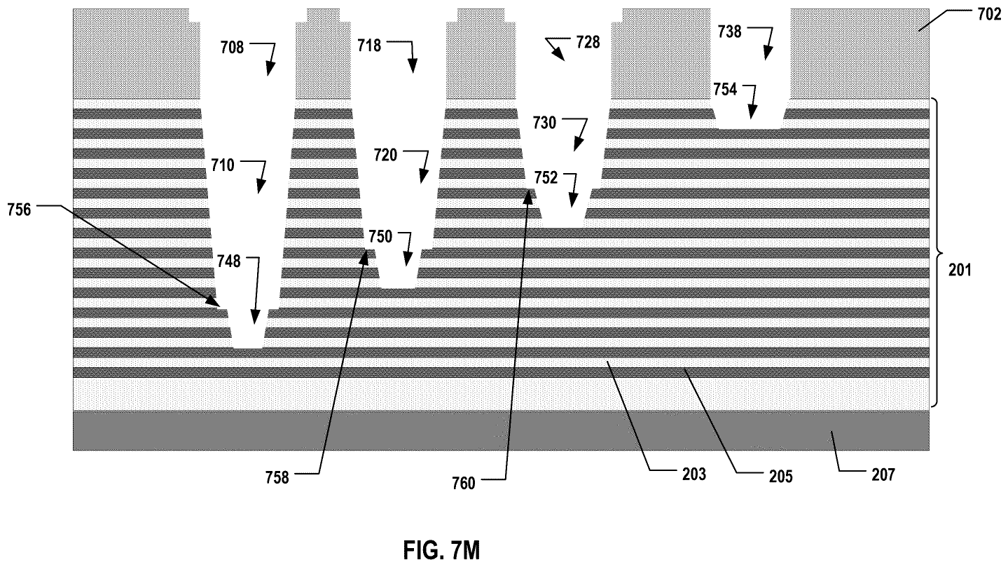

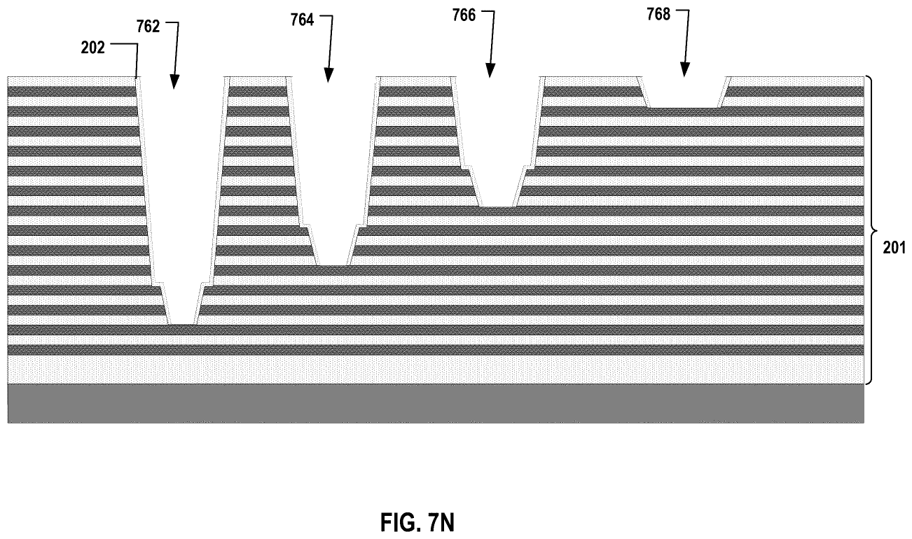

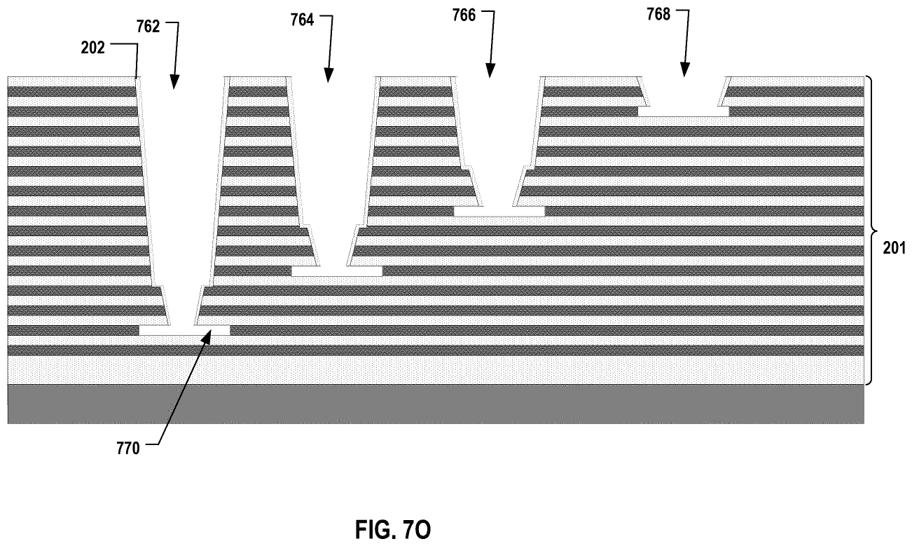

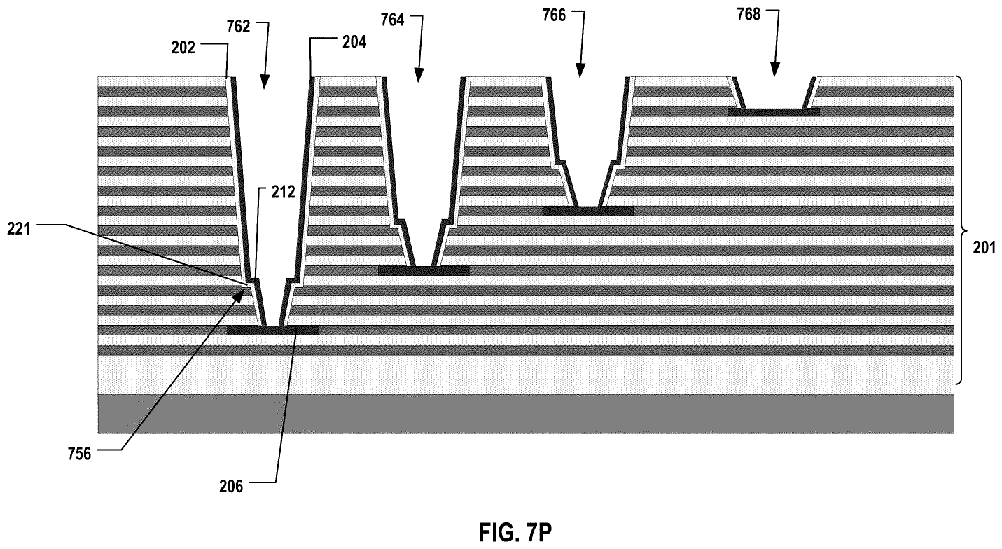

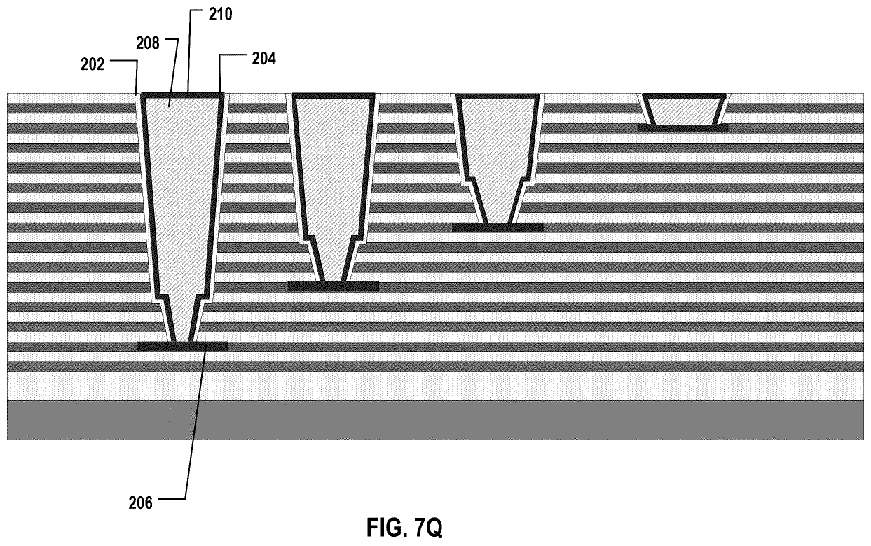

FIG. 2E illustrates contact depths of the contract structures in FIG. 2D, according to some aspects of the present disclosure. Specifically, Table 1 lists different contact depths for contact structures A, B, C, and D in the different groups. For example, a contact structure D in the fourth group may be formed in (i) a contact hole, which is formed by etching a number of layers in stack structure 201, and (ii) a lateral opening below the contact hole, e.g., as shown in FIGS. 7M-7Q below. The number of etched layers for the contact hole can be in a range of 0-127, such that a contact depth for the contact structure D can be in a depth range of 1-128 layers (e.g., the contact depth of the contact structure D=the number of etched layers for the contact hole+1, where “1” represents a layer of the lateral opening where a lateral contact member 206 of the contact structure D is formed). That is, the contact depth of the contact structure D can be any one of 1-128 layers.

Similarly, the number of etched layers for a contact hole of a contact structure C in the third group can be in a range of 128-255, such that a contact depth for the contact structure C can be in a depth range of 129-256 layers. The number of etched layers for a contact hole of a contact structure B in the second group can be in a range of 256-383, such that a contact depth for the contact structure B can be in a depth range of 257-384 layers. The number of etched layers for a contact hole of a contact structure A in the first group can be in a range of 384-311, such that a contact depth for the contact structure A can be in a depth range of 385-512 layers.

The contact depth of the contact structure D is smaller than the contact depth of the contact structure C. The contact depth of the contact structure C is smaller than the contact depth of the contact structure B. The contact depth of the contact structure B is smaller than the contact depth of the contact structure A.

FIG. 3A illustrates a cross-sectional side view of a memory device 100 having contact structures 106, according to some aspects of the present disclosure. One cross-section may be along the BB direction in core array region 101 in FIG. 1, and another cross-section may be along the CC direction in word line pick-up region 103 in FIG. 1. As shown in FIG. 3A, memory device 100 can include channel structures 110 in core array region 101. Each channel structure 110 can extend vertically through interleaved conductive layers 302 (word lines, e.g., tungsten) and first dielectric layers 203 (e.g., silicon oxide) in core array region 101 of stack structure 201 into semiconductor layer 207. Memory device 100 can also include dummy channel structures 112 in conductive portion 105 of word line pick-up region 103. Each dummy channel structure 112 can extend vertically through interleaved conductive layers 302 and first dielectric layers 203 in core array region 101 into semiconductor layer 207. Memory device 100 can further include slit structures 108 across core array region 101 and core array region 101. Each slit structure 108 can extend vertically through interleaved conductive layers 302 and first dielectric layers 203 in the second portion of stack structure 201 into semiconductor layer 207 as well.

As shown in FIG. 3A, slit structure 108 can include a slit spacer 309 that separates conductive layers 302 (word lines) between different blocks 102. In some implementations, slit structure 108 is an insulating structure that does not include any contact therein (i.e., not functioning as the source contact) and thus, does not introduce parasitic capacitance and leakage current with conductive layers 302 (word lines). In some implementations, slit structure 108 is a front-side source contact further including a conductive portion (e.g., including W, polysilicon, and/or TiN) circumscribed by slit spacer 309. As described below in detail, during the gate replacement process, the slit in which slit structure 108 is formed can serve as the passageway and starting point for forming conductive layers 302. As a result, slit structure 108 is surrounded by conductive layers 302 in either core array region 101 or conductive portion 105 of word line pick-up region 103.

As shown in FIG. 3A, in some implementations, memory device 100 further includes a plurality of drain select gate (DSG) channel structures 307 above and in contact with the upper ends of channel structures 110, respectively. Memory device 100 can further include a DSG layer 304 including a semiconductor layer (e.g., polysilicon layer) on stack structure 201 in core array region 101, but not in word line pick-up region 103, for example, as shown in FIG. 3A. Each DSG channel structure 307 can extend vertically through DSG layer 304 to be in contact with the upper end of a corresponding channel structure 110. In some implementations, memory device 100 further includes a stop layer 311 (e.g., silicon nitride layer) on DSG layer 304. DSG channel structure 307 can include a semiconductor layer (e.g., polysilicon) and a spacer surrounding the semiconductor layer. In some implementations, memory device 100 includes a DSG stack including one or more DSG layers and one or more dielectric layers (e.g., silicon oxide layers) interleaved stacked above stack structure 201.

As shown in FIG. 3A, memory device 100 can further include a local contact layer above stop layer 311 and stack structure 201. In some implementations, the local contact layer includes various local contacts, such as channel contacts 306 (a.k.a. bit line contacts) above and in contact with DSG channel structures 307 in core array region 101. The local contact layer can further include one or more interlayer dielectric (ILD) layers (also known as “intermetal dielectric (IMD) layers”) in which the local contacts can form. Channel contacts 306 in the local contact layer can include conductive materials including, but not limited to, W, Co, Cu, Al, silicides, or any combination thereof. The ILD layers in the local contact layer can include dielectric materials including, but not limited to, silicon oxide, silicon nitride, silicon oxynitride, low-k dielectrics, or any combination thereof.

Instead of having staircase structures and word line contacts landed on different levels/stairs of the staircase structures, memory device 100 can include stack structure 201 with uniform heights and contact structures 106 in dielectric portion 107 of word line pick-up region 103 for word line pick-up/fan-out. As shown in FIG. 3A, lateral contact member 206 of each contact structure 106 in dielectric portion 107 can extend laterally in the y-direction (the bit line direction) to be in contact with a corresponding conductive layer 302 (word line) in conductive portion 105 at the same level of stack structure 201. Since lateral contact member 206 is in contact with vertical contact member 204 of contact structure 106, each contact structure 106 is electrically connected to the corresponding conductive layer 302 (word line) across conductive portion 105 in word line pick-up region 103 and core array region 101, according to some implementations. In other words, contact structures 106 can extend vertically through stack structure 201 at different depths to be electrically connected to the word lines at different levels, respectively, to achieve word line pick-up/fan-out.

As described below in detail, during the gate replacement process, some of second dielectric layers 205 (e.g., silicon nitride) remain intact in dielectric portion 107 of word line pick-up region 103, and contact structures 106 are formed by etching first and second dielectric layers 203 and 205 in dielectric portion 107. As a result, contact structures 106 extend into interleaved first and second dielectric layers 203 and 205 and are surrounded by first and second dielectric layers 203 and 205 in dielectric portion 107 of word line pick-up region 103. The bottom of each contact structure 106 can be aligned with a corresponding second dielectric layer 205, as opposed to first dielectric layer 203, and the corresponding second dielectric layer 205 can be partially replaced with lateral contact member 206 to form the electrical connection between vertical contact member 204 of contact structure 106 and the corresponding conductive layer 302 (word line). Thus, in some implementations, lateral contact member 206 is sandwiched between two first dielectric layers 203, as opposed to two second dielectric layers 205, in dielectric portion 107 of word line pick-up region 103.

In some implementations as shown in FIG. 3A, due to the relatively large critical dimension compared with the word line contacts in some 3D memory devices caused by its fabrication process, contact structure 106 further includes a filler 208 circumscribed by vertical contact member 204. That is, a contact hole may not be fully filled with spacer 202 and vertical contact member 204, and the remaining space of the contact hole may be filled with dielectric materials, including, but not limited to, silicon oxide, silicon nitride, silicon oxynitride, or any combination thereof, as filler 208.

As shown in the enlarged view of FIG. 3B, in some implementations, channel structure 110 includes a channel hole filled with a semiconductor layer (e.g., as a channel layer 354) and a composite dielectric layer (e.g., as a memory layer 352). In some implementations, channel layer 354 includes silicon, such as amorphous silicon, polysilicon, or single crystalline silicon. For example, channel layer 354 may include polysilicon. In some implementations, memory layer 352 is a composite layer including a tunneling layer 360, a storage layer 358 (also known as a “charge trap layer”), and a blocking layer 356. The remaining space of the channel hole can be partially or fully filled with a filler including dielectric materials, such as silicon oxide, and/or an air gap. Channel structure 110 can have a cylinder shape (e.g., a pillar shape). The filler, channel layer 354, tunneling layer 360, storage layer 358, and blocking layer 356 are arranged radially from the center toward the outer surface of the pillar in this order, according to some implementations. Tunneling layer 360 can include silicon oxide, silicon oxynitride, or any combination thereof. Storage layer 358 can include silicon nitride, silicon oxynitride, silicon, or any combination thereof. Blocking layer 356 can include silicon oxide, silicon oxynitride, or any combination thereof. In one example, memory layer 352 can include a composite layer of silicon oxide/silicon oxynitride/silicon oxide (ONO).

As shown in FIG. 3B, memory device 100 can further include high dielectric constant (high-k) gate dielectric layers 362 each sandwiched between adjacent conductive layer 302 and first dielectric layer 203 in core array region 101 and conductive portion 105 of word line pick-up region 103. As described below in detail with respect to the fabrication process, high-k gate dielectric layers 362 may be formed prior to the formation of conductive layers 302, such that conductive layers 302 may be formed surrounded by high-k gate dielectric layers 362. Parts of high-k gate dielectric layers 362 that are laterally between memory layer 352 of channel structure 110 and conductive layers 302 can serve as the gate dielectrics of the memory cells. High-k gate dielectric layers 362 can include high-k dielectric materials, such as aluminum oxide (AlO), hafnium oxide (HfO), zirconium oxide (ZrO), or any combinations thereof.

As shown in FIG. 3B, compared with other high-k gate dielectric layers 362, part of high-k gate dielectric layer 362 surrounding conductive layer 302 (part of word line) that is in contact with lateral contact member 206 of contact structure 106 is removed to expose conductive layer 302 such that lateral contact member 206 can be electrically connected to conductive layer 302.

In some implementations, dummy channel structure 112 has the same structure as channel structure 110 because they are formed in the same fabrication process. Dummy channel structure 112, however, cannot perform the same memory functions as channel structure 110 at least because dummy channel structures 112 are not in contact with any DSG channel structures 307 or any local contacts (e.g., channel contacts 306) in the local contact layer to pick-up/fan-out dummy channel structures 112, as shown in FIG. 3A, according to some implementations. It is understood that in some examples, dummy channel structures 112 and channel structure 110 may have different structures and may be formed in different fabrication processes. For example, dummy channel structures 112 may be filled with dielectric material(s) without semiconductor materials (as channel layer 354). Nevertheless, both dummy channel structures 112 and channel structures 110 can perform the mechanical supporting functions to stack structure 201, in particular, during the gate replacement process, as described below in detail with respect to the fabrication processes.

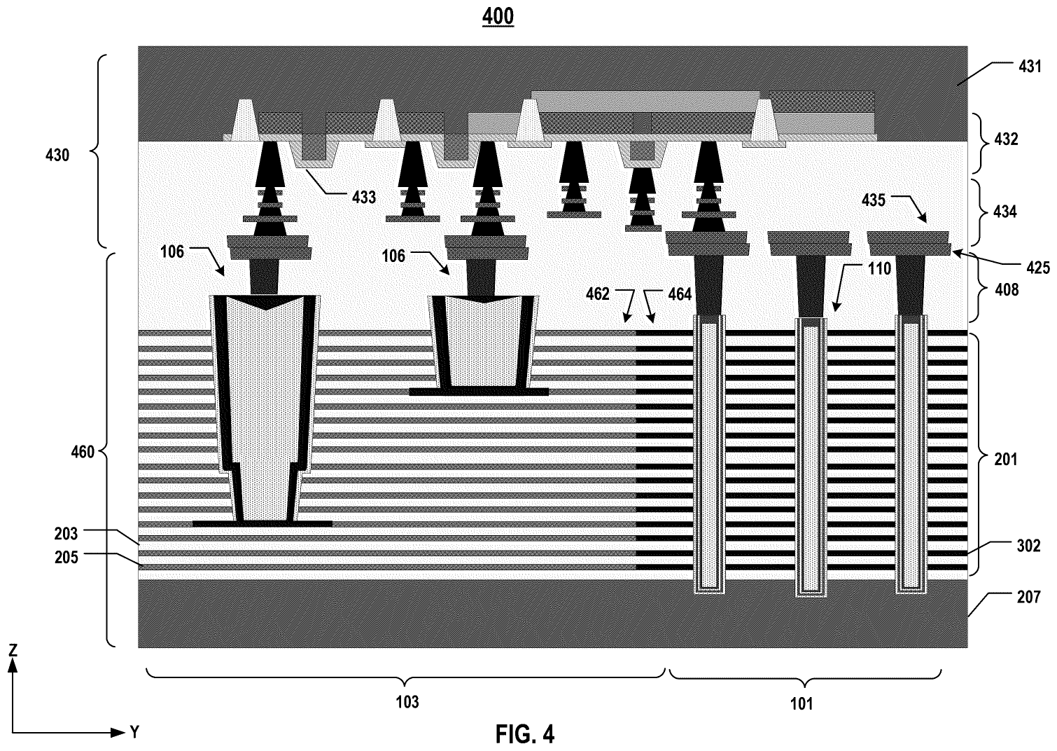

FIG. 4 illustrates a cross-sectional side view of a memory device 400 including a peripherical circuit, according to some aspects of the present disclosure. Memory device 400 may be, for example, an example implementation of memory device 100. The cross-section may be along a direction like the DD direction in FIG. 1. FIG. 4 may include components like those of FIGS. 1, 2A-2E, and 3A-3B, and a similar description will not be repeated herein. Memory device 400 may include a semiconductor structure 460 and peripheral circuit 430 stacked on and connected to semiconductor structure 460.

Peripheral circuit 430 can include a semiconductor layer 431 and a device layer 432 disposed on and in contact with semiconductor layer 431. In some implementations, device layer 432 includes one or more circuits, such as driving circuits, page buffer circuits, and logic circuits. In some implementations, device layer 432 includes a plurality of transistors 433 in contact with semiconductor layer 431. Transistors 433 can include any transistors, such as Metal-Oxide Semiconductor (MOS) transistors, Complementary Metal-Oxide Semiconductor (CMOS) transistors, or transistors of other types.

In some implementations, peripheral circuit 430 may further include a connection layer 434 and a bonding layer 435. Connection layer 434 may be connected to device layer 432 to transfer electrical signals to and from device layer 432. Connection layer 434 can be vertically between bonding layer 435 and device layer 432. Connection layer 434 can include a plurality of interconnects (also referred to herein as “contacts”), including lateral lines and vias. As used herein, the term “interconnects” can broadly include any suitable types of interconnects, such as middle-end-of-line (MEOL) interconnects and back-end-of-line (BEOL) interconnects. The interconnects in connection layer 434 can be coupled to transistors 433 in device layer 432. Connection layer 434 can further include one or more interlayer dielectric (ILD) layers (also known as “intermetal dielectric (IMD) layers”) in which the lateral lines and vias can form. That is, connection layer 434 can include lateral lines and vias in multiple ILD layers. In some implementations, the devices in device layer 432 are coupled to one another through the interconnects in connection layer 434. For example, different transistors 433 may be coupled to one another through connection layer 434. The interconnects in connection layer 434 can include conductive materials including, but not limited to, W, Co, Cu, Al, silicides, or any combination thereof. The ILD layers in connection layer 434 can include dielectric materials including, but not limited to, silicon oxide, silicon nitride, silicon oxynitride, low dielectric constant (low-k) dielectrics, or any combination thereof. In some implementations, the interconnects in connection layer 434 include W, which has a relatively high thermal budget (compatible with high-temperature processes) and good quality (fewer defects, e.g., voids) among conductive metal materials.

Semiconductor structure 460 may be divided into at least core array region 101 and word line pick-up region 103. In some implementations, semiconductor structure 460 may include semiconductor layer 207 and stack structure 201 over semiconductor layer 207. Stack structure 201 may include alternating first layers and first dielectric layers 203. Stack structure 201 may include a first portion 462 and a second portion 464 adjacent to first portion 462. In some examples, second portion 464 of stack structure 201 may include a part of stack structure 201 in core array region 101 and conductive portion 105 of word line pick-up region 103. First portion 462 of stacks structure 201 may include a part of stack structure 201 in dielectric portion 107 of word line pick-up region 103.

The first layers of first portion 462 may include second dielectric layers 205, whereas the first layers of second portion 464 may include conductive layers 302. For example, first portion 462 of stack structure 201 may include interleaved second dielectric layers 205 and first dielectric layers 203. Second portion 464 of stack structure 201 may include interleaved conductive layers 302 and first dielectric layers 203.

In some implementations, semiconductor structure 460 may further include contact structures 116 extending through first portion 462. Peripheral circuit 430 may be connected to contact structures 116. Semiconductor structure 460 may further include channel structures 110 extending through second portion 464 into semiconductor layer 207.

As shown in FIG. 4, semiconductor structure 460 may also include a connection layer 408 formed on channel structures 110 and electrically connected to channel structures 110 to transfer electrical signals to and from memory cells formed in channel structures 110. Connection layer 408 may also be connected to contact structures 106. Semiconductor structure 460 may include bonding layer 425 above and in contact with connection layer 408. In some implementations, semiconductor structure 460 and peripheral circuit 430 may be coupled to one another by hybrid bonding. For example, connection layer 434 of peripheral circuit 430 can be bonded to connection layer 408 of semiconductor structure 460 using bonding layers 435 and 425. The bonding contacts and surrounding dielectrics in each of bonding layers 425, 435 can be used for hybrid bonding.

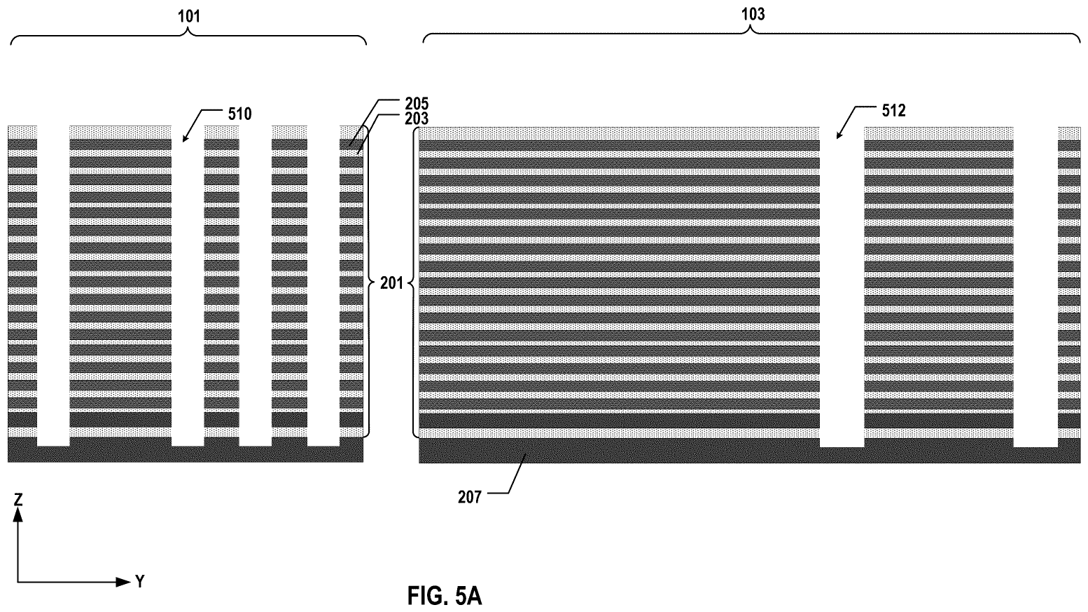

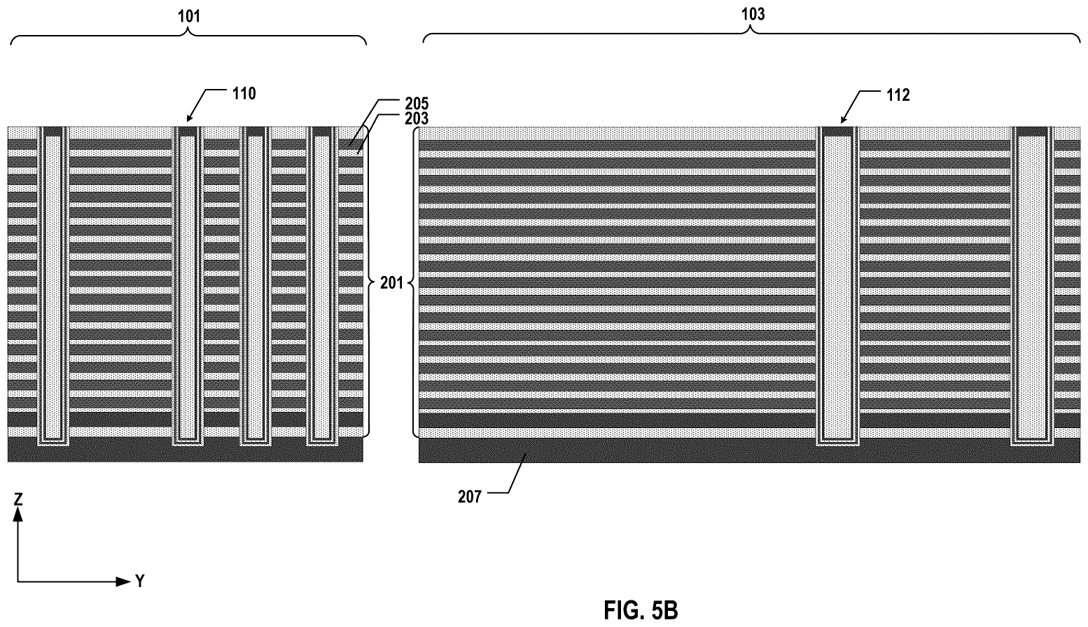

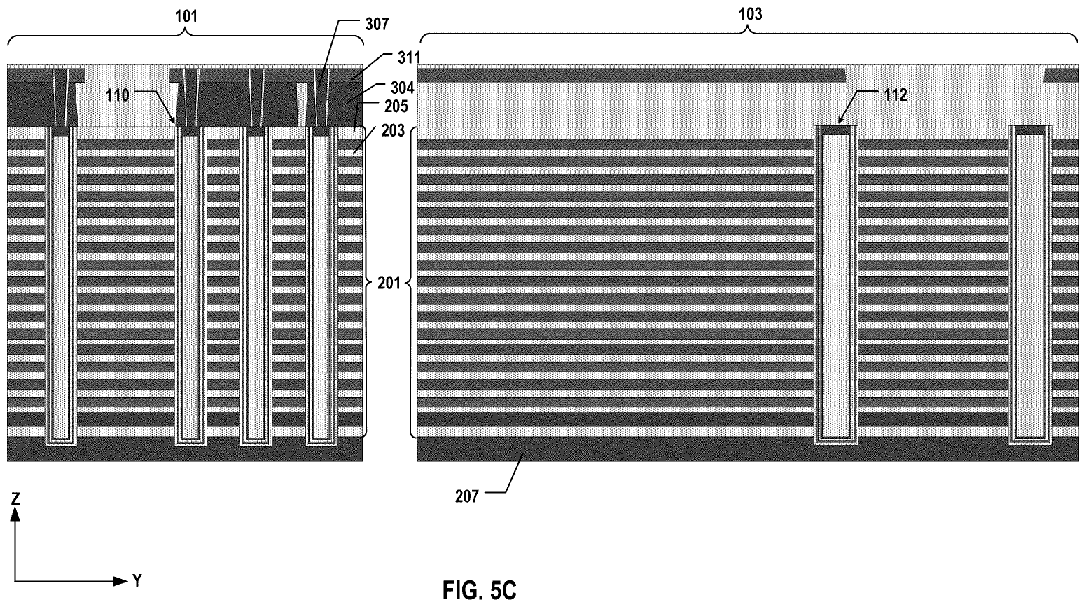

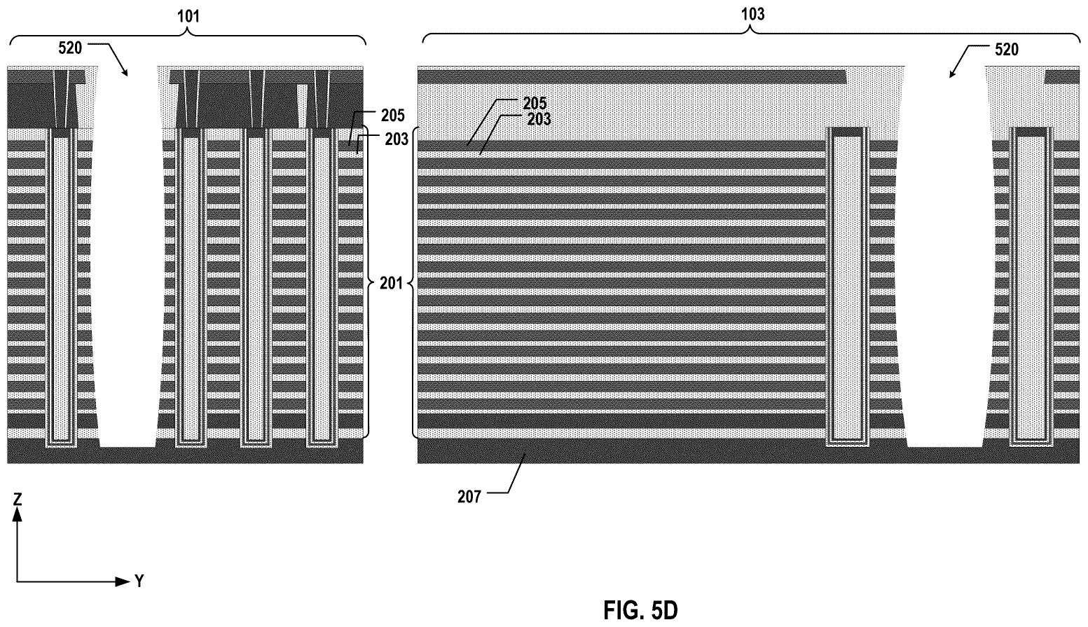

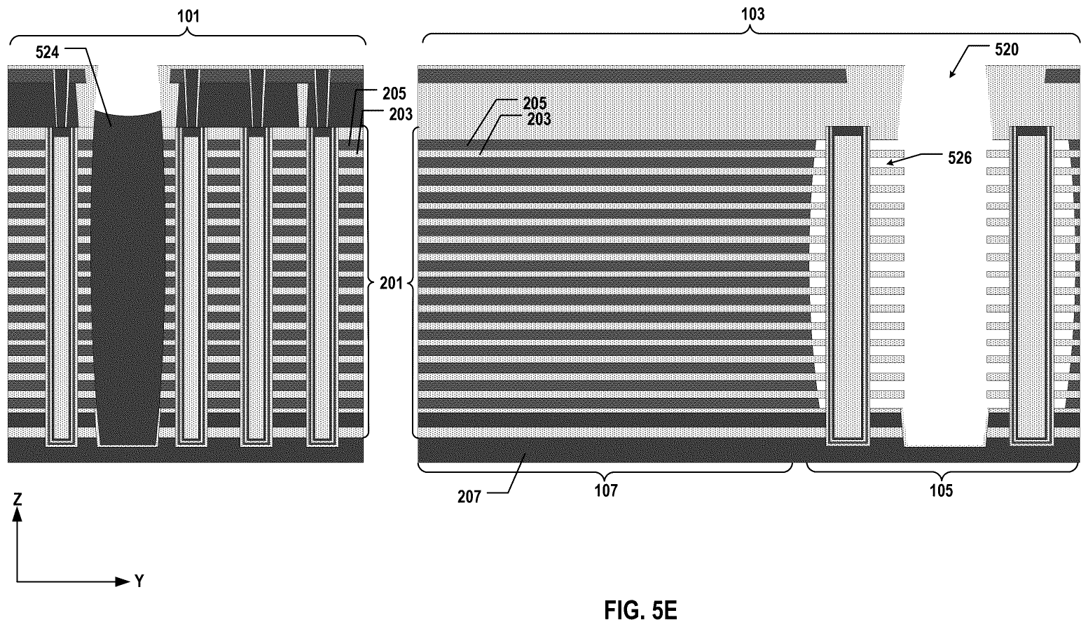

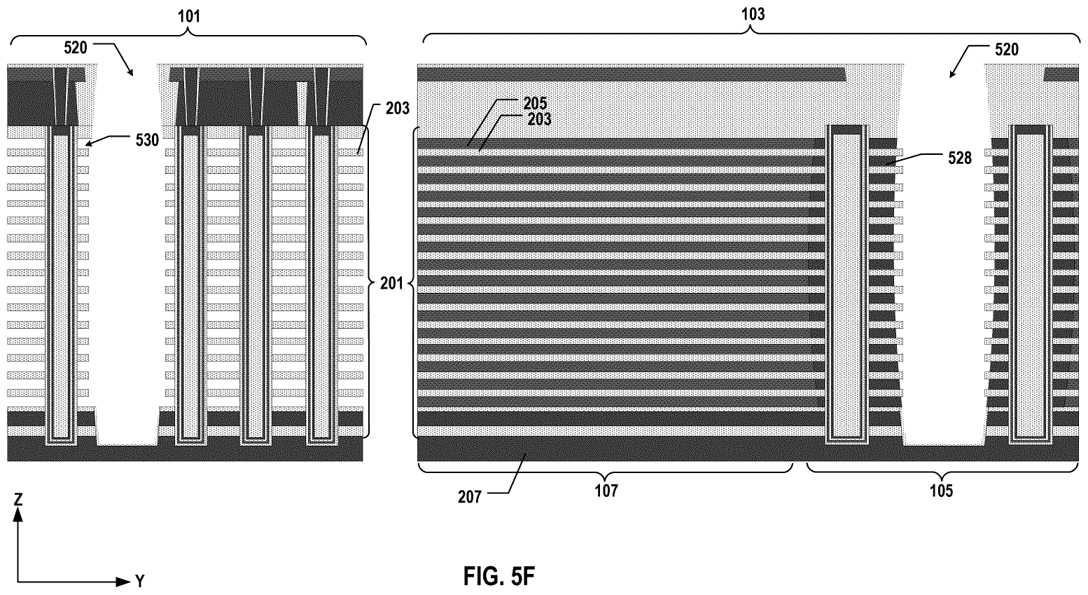

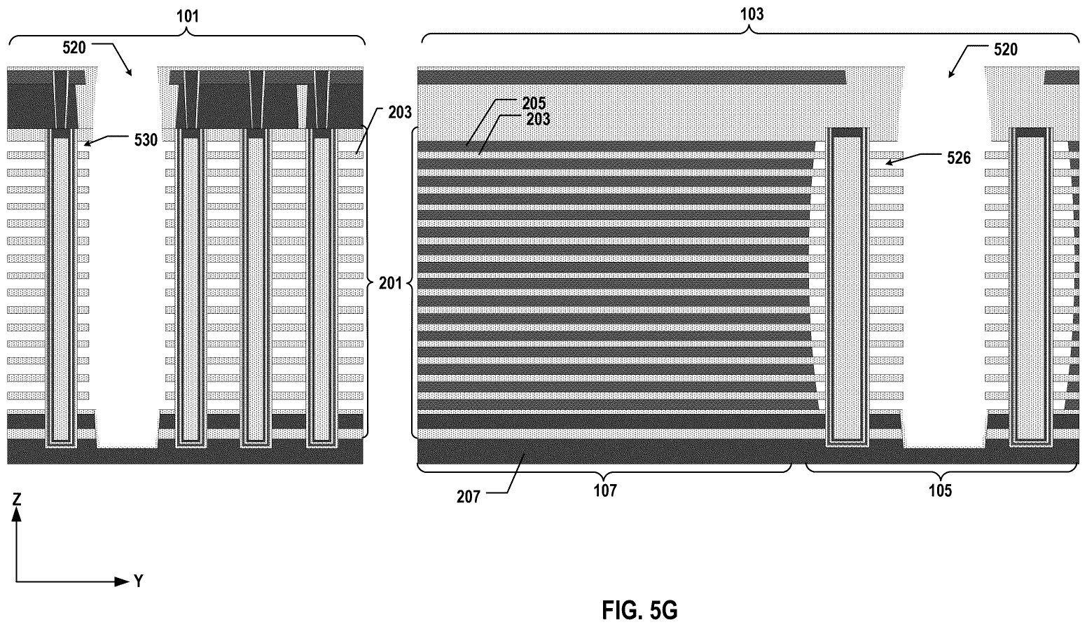

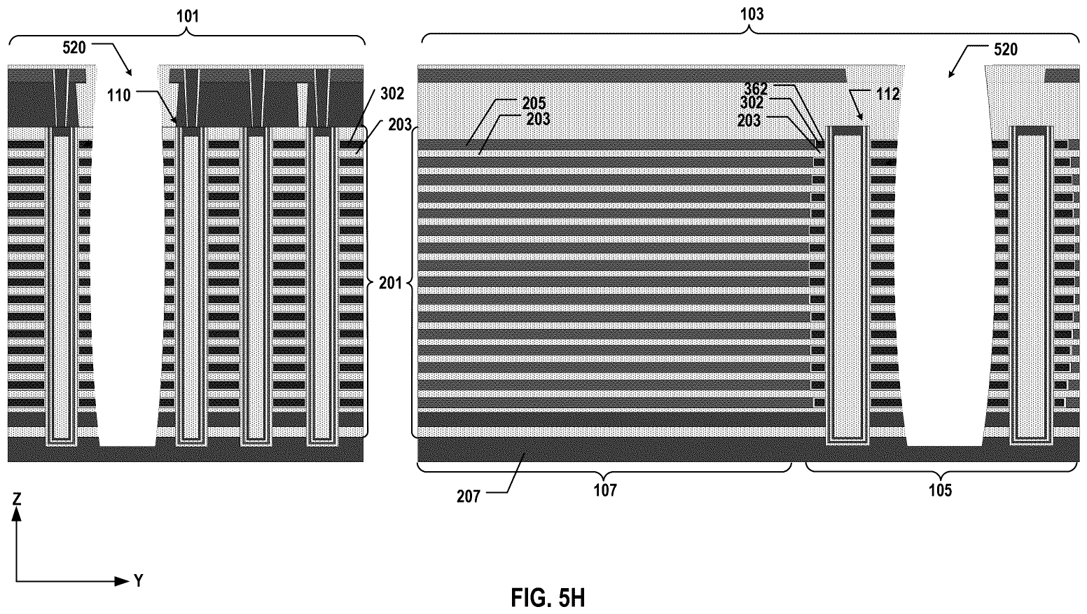

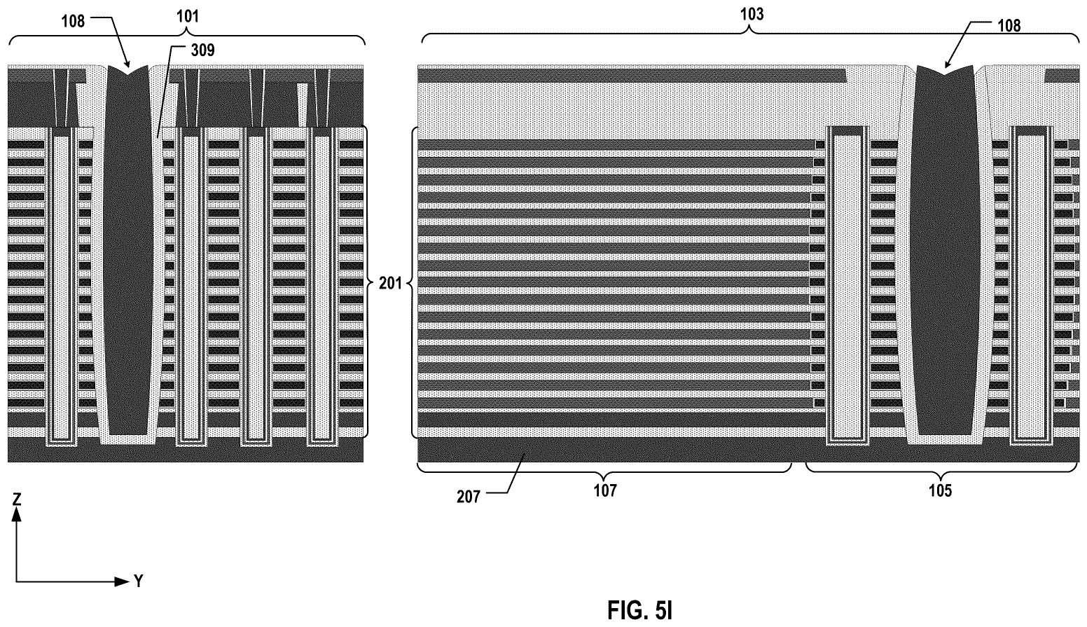

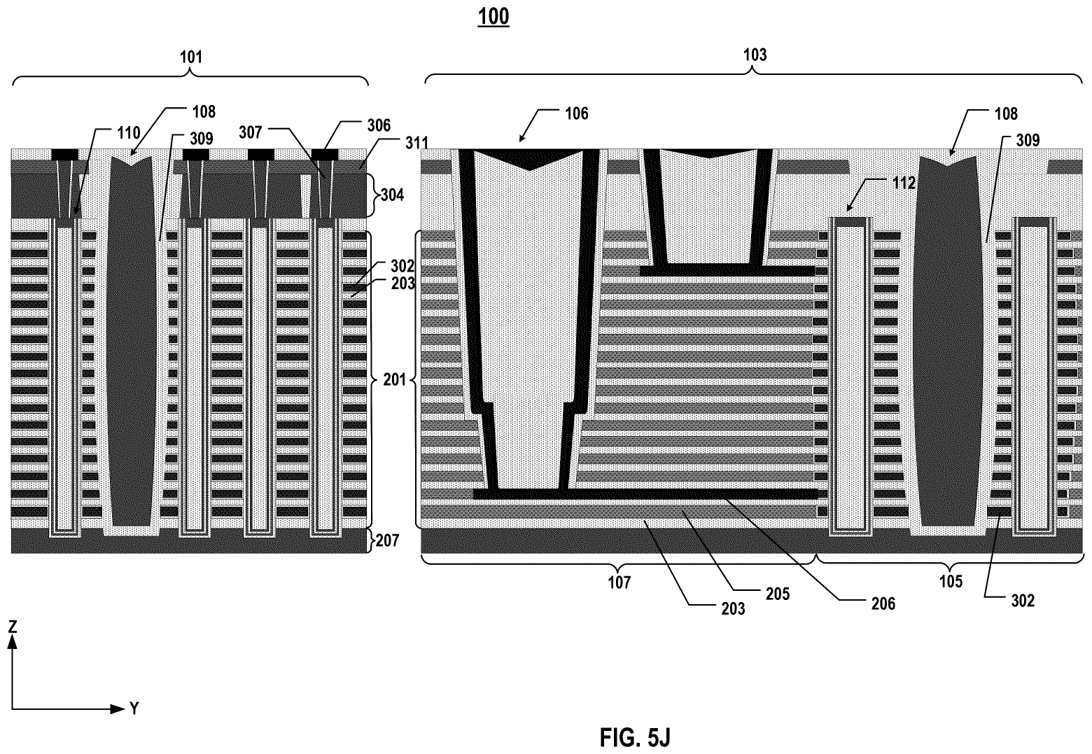

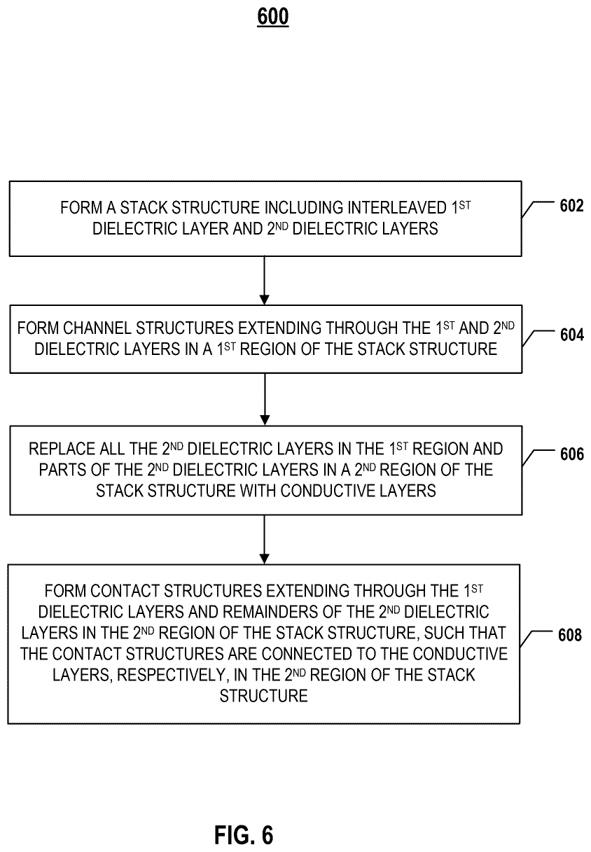

FIGS. 5A-5J illustrate a fabrication process for forming memory device 100 having contact structures 106, according to some aspects of the present disclosure. FIG. 6 is a flowchart of a method 600 for forming memory device 100 having contact structures 106, according to some aspects of the present disclosure. FIGS. 5A-5J and 6 will be described together. It is understood that the operations shown in method 600 are not exhaustive and that other operations can be performed as well before, after, or between any of the illustrated operations. Further, some of the operations may be performed simultaneously, or in a different order than shown in FIG. 6.

Referring to FIG. 6, method 600 starts at operation 602, in which a stack structure including interleaved first dielectric layers and second dielectric layers is formed. The first dielectric layers can include silicon oxide, and the second dielectric layers can include silicon nitride. In some implementations, to form the stack structure, the first dielectric layers and the second dielectric layers are alternatingly deposited above a semiconductor layer such as a substrate. The substrate can be a silicon substrate.

Method 600 proceeds to operation 604, as illustrated in FIG. 6, in which channel structures extending through the first dielectric layers and the second dielectric layers are formed in a first region of the stack structure. In some implementations, to form the channel structure, a channel hole extending vertically through the stack structure is formed, and a memory layer and a channel layer are sequentially formed over sidewalls of the channel hole. In some implementations, dummy channel structures extending through the first dielectric layers and the second dielectric layers are formed in a second region of the stack structure in the same process of forming the channel structures. That is, channel structures and dummy channel structures can be simultaneously formed through the first dielectric layers and the second dielectric layers in the first region and the second region of the stack structure, respectively.

As illustrated in FIG. 5A, stack structure 201 including multiple pairs of a first dielectric layer 203 and a second dielectric layer 205 (a.k.a., a stack sacrificial layer) is formed above semiconductor layer 207. Stack structure 201 includes vertically interleaved first dielectric layers 203 and second dielectric layers 205, according to some implementations. First and second dielectric layers 203 and 205 can be alternatingly deposited above semiconductor layer 207 to form stack structure 201. In some implementations, each first dielectric layer 203 includes a layer of silicon oxide, and each second dielectric layer 205 includes a layer of silicon nitride. Stack structure 201 can be formed by one or more thin film deposition processes including, but not limited to, chemical vapor deposition (CVD), physical vapor deposition (PVD), atomic layer deposition (ALD), or any combination thereof.

Channel holes 510, each of which is an opening extending vertically through stack structure 201, can be formed in core array region 101. In some implementations, a plurality of openings are formed, such that each opening becomes the location for growing an individual channel structure 110 in the later process. In some implementations, fabrication processes for forming channel holes 510 of channel structure 110 include wet etching and/or dry etching, such as deep-ion reactive etching (DRIE). A dummy channel hole 512, which is another opening extending vertically through stack structure 201, can be formed in word line pick-up region 103 simultaneously as channel hole 510 by the same wet etching and/or dry etching, such as DRIE.

As illustrated in FIG. 5B, channel structures 110 can be formed in channel holes 510 in core array region 101 of stack structure 201. A memory layer (including a blocking layer, a storage layer, and a tunneling layer) and a channel layer are sequentially formed in this order along sidewalls and the bottom surface of channel hole 510. In some implementations, the memory layer is first deposited along the sidewalls and bottom surface of channel hole 510, and the semiconductor channel is then deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are subsequently deposited to form the memory layer and the channel layer of channel structure 110.

In some implementations, as illustrated in FIG. 5B, dummy channel structure 112 can be formed in dummy channel hole 512 in word line pick-up region 103 of stack structure 201, in the same process of forming channel structures 110. Dummy channel structure 112 can be formed simultaneously as channel structure 110 by the same thin film deposition processes, such as ALD, CVD, PVD, any other suitable processes, or any combination thereof that deposit a memory layer (including a blocking layer, a storage layer, and a tunneling layer) and a channel layer, a memory layer (including a blocking layer, a storage layer, and a tunneling layer), and a channel layer. It is understood that in some examples, dummy channel structure 112 may be formed in a separate process from channel structures 110.

As illustrated in FIG. 5C, DSG layer 304 and stop layer 311 are formed on core array region 101 of stack structure 201. DSG layer 304 can include a semiconductor layer, such as a polysilicon layer, and stop layer 311 can include a silicon nitride layer. DSG layer 304 and stop layer 311 can be sequentially deposited on core array region 101, but not on word line pick-up region 103, of stack structure 201 using one or more thin film deposition processes including, but not limited to, CVD, PVD, ALD, or any combination thereof. DSG channel structures 307 can be formed extending vertically through DSG layer 304 and stop layer 311 to be in contact with the upper ends of channel structures 110, but not dummy channel structure 112, as shown in FIG. 5C. To form DSG channel structures 307, DSG holes can be etched through DSG layer 304 and stop layer 311 to expose the upper ends of channel structures 110, respectively, and a spacer (e.g., having silicon oxide) and a semiconductor layer (e.g., having polysilicon) can be sequentially deposited into the DSG holes using one or more thin film deposition processes, such as CVD, PVD, ALD, or any combination thereof, to fill the DSG holes.

Method 600 proceeds to operation 606, as illustrated in FIG. 6, in which all the second dielectric layers in the first region and parts of the second dielectric layers in the second region of the stack structure are replaced with conductive layers, for example, by a gate replacement process. The conductive layers can include a metal.

As illustrated in FIG. 5D, a slit 520 is an opening that extends vertically through stop layer 311, DSG layer 304, and first dielectric layers 203 and second dielectric layers 205 (a.k.a., stack sacrificial layers) of stack structure 201 until semiconductor layer 207. Slit 520 can also extend laterally across core array region 101 and word line pick-up region 103 in the x-direction (the word line direction), for example, corresponding to slit structure 108 in FIG. 1. In some implementations, fabrication processes for forming slit 520 include wet etching and/or dry etching, such as DRIE, of first dielectric layers 203 and second dielectric layers 205. The etching process through stack structure 201 may not stop at the top surface of semiconductor layer 207 and may continue to etch part of semiconductor layer 207 to ensure that slit 520 extends vertically all the way through all first dielectric layers 203 and second dielectric layers 205 of stack structure 201.

As illustrated in FIG. 5E, the part of slit 520 in core array region 101 is covered by a sacrificial layer 524. In some implementations, sacrificial layer 524 different from first dielectric layers 203 and second dielectric layers 205, such as a polysilicon layer or a carbon layer, is deposited into slit 520 using one or more thin film deposition processes, such as CVD, PVD, ALD, or any combination thereof, to at least partially fill slit 520 (covering the exposed first dielectric layers 203 and second dielectric layers 205 in slit 520). Sacrificial layer 524 can then be patterned using lithography and wet etching and/or dry etching to remove the part of sacrificial layer 524 in word line pick-up region 103, leaving only the part of sacrificial layer 524 in core array region 101 to cover only the part of slit 520 in core array region 101.

Parts of second dielectric layers 205 in conductive portion 105 of word line pick-up region 103 are removed by wet etching to form lateral recesses 526, leaving the remainders of second dielectric layers 205 in dielectric portion 107 of word line pick-up region 103 intact. In some implementations, the parts of second dielectric layers 205 are wet etched by applying a wet etchant through the part of slit 520 in word line pick-up region 103 that is uncovered by sacrificial layer 524, creating lateral recesses 526 interleaved between first dielectric layers 203. The wet etchant can include phosphoric acid for etching second dielectric layers 205 including silicon nitride. In some implementations, the etching rate and/or etching time are controlled to remove only the parts of second dielectric layers 205 in conductive portion 105, leaving the remainders of second dielectric layers 205 intact in dielectric portion 107. By controlling the etching time, the wet etchant does not travel all the way to completely remove second dielectric layers 205 in word line pick-up region 103, thereby defining two portions in word line pick-up region 103—dielectric portion 107 in which second dielectric layers 205 are removed, and dielectric portion 107 in which second dielectric layers 205 remain. As illustrated in FIG. 7E, since the part of slit 520 in core array region 101 is covered by sacrificial layer 524 that is resistant to the etchant for removing second dielectric layers 205, all second dielectric layers 205 remain intact in core array region 101.

As illustrated in FIG. 5F, the part of slit 520 in core array region 101 is re-opened by removing sacrificial layer 524 (shown in FIG. 5E) to expose first dielectric layers 203 and second dielectric layers 205. In some implementations, sacrificial layer 524 is selectively etched away from the part of slit 520 in core array region 101, for example, using potassium hydroxide (KOH) for etching sacrificial layer 524 having polysilicon to open the part of slit 520 in core array region 101.

Also, as illustrated in FIG. 5F, lateral recesses 526 (shown in FIG. 5E) and the part of slit 520 in word line pick-up region 103 are covered by a sacrificial layer 528. In some implementations, sacrificial layer 528 that is different from first dielectric layers 203 and second dielectric layers 205, such as a polysilicon layer or a carbon layer, is deposited into lateral recesses 526 and slit 520 using one or more thin film deposition processes, such as CVD, PVD, ALD, or any combination thereof, to at least partially fill slit 520 (covering the exposed first dielectric layers 203 and second dielectric layers 205). Sacrificial layer 528 can then be patterned using lithography and wet etching and/or dry etching to remove the part of sacrificial layer 528 in core array region 101, leaving only the part of sacrificial layer 528 in word line pick-up region 103 to cover only lateral recesses 526 and the part of slit 520 in word line pick-up region 103, but not in core array region 101. It is understood that lateral recesses 526 may be considered as parts of slit 520 in word line pick-up region 103. Thus, even if only lateral recesses 526 are fully or partially filled by sacrificial layer 528 (e.g., as shown in FIG. 5F), the part of slit 520 in word line pick-up region 103 may still be considered as being covered.

All second dielectric layers 205 in core array region 101 (as shown in FIG. 5E) are fully removed by wet etching to form lateral recesses 530. In some implementations, second dielectric layers 205 are wet etched by applying a wet etchant through the part of slit 520 in core array region 101 that is uncovered by sacrificial layer 528, creating lateral recesses 530 interleaved between first dielectric layers 203. The wet etchant can include phosphoric acid for etching second dielectric layers 205 including silicon nitride. In some implementations, the etching rate and/or etching time are controlled to ensure that all second dielectric layers 205 in core array region 101 are completely etched away. As illustrated in FIG. 5F, since the part of slit 520 in word line pick-up region 103 is covered by sacrificial layer 528 that is resistant to the etchant for removing second dielectric layers 205, the remainders of second dielectric layers 205 in dielectric portion 107 of word line pick-up region 103 remain intact.

As illustrated in FIG. 5G, the part of slit 520 in word line pick-up region 103 is re-opened by removing sacrificial layer 528 (shown in FIG. 5F) to expose first dielectric layers 203 and the remainder of second dielectric layers 205 in word line pick-up region 103. In some implementations, sacrificial layer 528 is selectively etched away from the part of slit 520 in word line pick-up region 103, for example, using KOH for etching sacrificial layer 528 having polysilicon, to open the part of slit 520 (and lateral recesses 526) in word line pick-up region 103.

As illustrated in FIG. 5H, conductive layers 302 are deposited into lateral recesses 530 and 526 (shown in FIG. 5G) in core array region 101 and conductive portion 105 of word line pick-up region 103 through slit 520. In some implementations, high-k gate dielectric layers 362 are deposited into lateral recesses 526 and 530 prior to conductive layers 302, such that conductive layers 302 are deposited on and surrounded by high-k gate dielectric layers 362, for example, corresponding to the example shown in FIG. 3B. Conductive layers 302, such as metal layers, can be deposited using one or more thin film deposition processes, such as ALD, CVD, PVD, any other suitable processes, or any combination thereof.

As illustrated in FIG. 5I, a slit spacer 309 is formed in slit 520 (shown in FIG. 5H) to form slit structure 108 extending vertically through interleaved conductive layers 302 and first dielectric layers 203 of stack structure 201 and laterally across core array region 101 and conductive portion 105 of word line pick-up region 103. Slit spacer 309 can be formed by depositing dielectrics into slit 520 using one or more thin film deposition processes, such as ALD, CVD, PVD, any other suitable processes, or any combination thereof. In some implementations, conductive materials (e.g., as a source contact) are deposited into slit 520 after slit spacer 309 as part of slit structure 108.

Method 600 proceeds to operation 608, as illustrated in FIG. 6, in which contact structures extending through the first dielectric layers and remainders of the second dielectric layers in the second region of the stack structure are formed, such that the contact structures are connected to the conductive layers, respectively, in the second region of the stack structure.

As illustrated in FIG. 5J, contact structures 106 are formed in dielectric portion 107 of word line pick-up region 103, by performing operations like those described below with reference to FIGS. 7A-7Q. As a result, memory device 100 shown in FIG. 3A is formed.

FIGS. 7A-7Q illustrate a fabrication process for forming contact structures 106 in stack structure 201, according to some aspects of the present disclosure. By way of examples, contact structures 106 formed in fabrication process of FIGS. 7A-7Q may be divided into four groups (e.g., the four groups shown in FIGS. 2D and 2E). With respect to FIGS. 7A-7M, a first set of contact holes for the first group, a second set of contact holes for the second group, a third set of contact holes for the third group, and a fourth set of contact holes for the fourth group may be formed in stack structure 201. With respect to FIGS. 7N-7Q, the first group of contact structures, the second group of contact structures, the third group of contact structures, and the fourth group of contact structures may be formed in the first set of contact holes, the second set of contact holes, the third set of contact holes, and the fourth set of contact holes, respectively.

The first group of contact structures may include a first set of contact shoulders 212 located in a first stack pair. The second group of contact structures may include a second set of contact shoulders 212 located in a second stack pair. The third group of contact structures may include a third set of contact shoulders located in a third stack pair. The fourth group of contact structures may include a fourth set of contact shoulders 212 located in a fourth stack pair. The first, second, third, and fourth stack pairs are different stack pairs.

To form the first set of contact holes for the first group, as shown in FIG. 7A, a block layer 702 can be formed on stack structure 201. Block layer 702 may include, for example, AlO or polysilicon. Block layer 702 can be formed by depositing a semiconductor material, such as polysilicon, over stack structure 201 using one or more thin film deposition processes, such as ALD, CVD, PVD, any other suitable processes, or any combination thereof.

A first mask 703 may be deposited over block layer 702. First mask 703 can be a hard mask (HM). For example, first mask 703 may include a carbon layer 704 and a silicon oxynitride (SiON) layer 706. Carbon layer 704 can be formed by depositing carbon over block layer 702 using one or more thin film deposition processes, such as ALD, CVD, PVD, any other suitable processes, or any combination thereof. SiON layer 706 can be formed by depositing SiON over carbon layer 704 using one or more thin film deposition processes, such as ALD, CVD, PVD, any other suitable processes, or any combination thereof.

As shown in FIG. 7B, a set of mask openings 708 extending through first mask 703 (including carbon layer 704 and SiON layer 706) and block layer 702 may be formed. In some implementations, fabrication processes for forming mask openings 708 may include wet etching and/or dry etching, such as deep-ion reactive etching (DRIE).

As shown in FIG. 7C, stack structure 201 may be etched through the set of mask openings 708 to form a first set of openings 710 into stack structure 201 for the first group, respectively. First mask 703 (shown in FIG. 7B) may be removed to expose block layer 702. Without loss of generality, only one mask opening 708 and one opening 710 are illustrated in the figures. It is contemplated that the set of mask openings 708 may include one or more mask openings 708, and the first set of openings 710 may include one or more openings 710, which is not limited herein. The first set of openings 710 may have a first depth 709 in the z-direction, and bottoms of the first set of openings 710 are in the same first stack pair (e.g., first dielectric layer 203A and second dielectric layer 205A).

For example, the first group is the first group of contact structures A in FIGS. 2D-2E. The first set of openings 710 are formed by etching 384 layers of stack structure 201 through the first set of mask openings 708, respectively. That is, first depth 709 of openings 710 may be 384 layers.

In some implementations, fabrication processes for forming openings 710 include wet etching and/or dry etching, such as deep-ion reactive etching (DRIE). In some implementations, openings 710 can be formed using a chopping process. As used herein, a “chopping” process is a process that increases the depth of one or more openings extending through interleaved first and second dielectric layers by a plurality of etching cycles. Each etch cycle can include one or more dry etch and/or wet etch processes that etch one pair of first and second dielectric layers, i.e., reducing the depth by a stack pair.

To form the second set of contact holes for the second group, as shown in FIG. 7D, a second mask 713 may be deposited over block layer 702. Second mask 713 can be a hard mask. For example, second mask 713 may include a carbon layer 714 and a SiON layer 716. Carbon layer 714 and SiON layer 716 may be formed by performing processes like those of carbon layer 704 and SiON layer 706 in FIG. 7A, respectively, and a similar description will not be repeated herein.

As shown in FIG. 7E, a set of mask openings 718 extending through second mask 713 (including carbon layer 714 and SiON layer 716) and block layer 702 may be formed. In some implementations, fabrication processes for forming mask openings 718 may include wet etching and/or dry etching, such as deep-ion reactive etching (DRIE).

As shown in FIG. 7F, stack structure 201 may be etched through the set of mask opening 718 to form a second set of openings 720 in stack structure 201 for the second group, respectively. Second mask 713 (shown in FIG. 7E) may be removed to expose block layer 702. Without loss of generality, only one mask opening 718 and one opening 720 are illustrated in the figures. It is contemplated that the set of mask openings 718 may include one or more mask openings 718, and the second set of openings 720 may include one or more openings 720, which is not limited herein. The second set of openings 720 may have a second depth 722 in the z-direction, and bottoms of the second set of openings 720 are in the same second stack pair (e.g., first dielectric layer 203B and second dielectric layer 205B). The second set of openings 720 may be formed by performing processes like those described above for the first set of openings 710 in FIG. 7C, and a similar description will not be repeated herein.

For example, the second group is the second group of contact structures B in FIGS. 2D-2E. The second set of openings 720 are formed by etching 256 layers of stack structure 201 through the set of mask openings 718, respectively. That is, second depth 722 of openings 720 may be 256 layers.

To form the third set of contact holes for the third group, as shown in FIG. 7G, a third mask 723 may be deposited over block layer 702. Third mask 723 can be a hard mask. For example, third mask 723 may include a carbon layer 724 and a SiON layer 726. Carbon layer 724 and SiON layer 726 may be formed by performing processes like those of carbon layer 704 and SiON layer 706 in FIG. 7A, respectively, and a similar description will not be repeated herein.

As shown in FIG. 7H, a set of mask openings 728 extending through third mask 723 (including carbon layer 724 and SiON layer 726) and block layer 702 may be formed. In some implementations, fabrication processes for forming mask opening s728 may include wet etching and/or dry etching, such as deep-ion reactive etching (DRIE).

As shown in FIG. 7I, stack structure 201 may be etched through the set of mask openings 728 to form a third set of openings 730 into stack structure 201 for the third group, respectively. Third mask 723 (shown in FIG. 7H) may be removed to expose block layer 702. Without loss of generality, only one mask opening 728 and one opening 730 are illustrated in the figures. It is contemplated that the set of mask openings 728 may include one or more mask openings 728, and the third set of openings 730 may include one or more openings 730, which is not limited herein. The third set of openings 730 may have a third depth 732 in the z-direction, and bottoms of the third set of openings 730 are in the same third stack pair (e.g., first dielectric layer 203C and second dielectric layer 205C). The third set of openings 730 may be formed by performing processes like those described above for the first set of openings 710 in FIG. 7C, and a similar description will not be repeated herein.

For example, the third group is the third group of contact structures C in FIGS. 2D-2E. The third set of openings 730 are formed by etching 128 layers of stack structure 201 through the set of mask openings 728, respectively. That is, third depth 732 of openings 730 may be 128 layers.

To form the fourth set of contact holes for the fourth group (e.g., the fourth group being the fourth group of contact structures D in FIGS. 2D-2E), as shown in FIG. 7J, a fourth mask 733 may be deposited over block layer 702. Fourth mask 733 can be a hard mask. For example, fourth mask 733 may include a carbon layer 734 and a SiON layer 736. Carbon layer 734 and SiON layer 736 may be formed by performing processes like those of carbon layer 704 and SiON layer 706 in FIG. 7A, respectively, and a similar description will not be repeated herein.

As shown in FIG. 7K, a set of mask openings 738 extending through third mask 733 (including carbon layer 734 and SiON layer 736) and block layer 702 may be formed. In some implementations, fabrication processes for forming mask openings 738 may include wet etching and/or dry etching, such as deep-ion reactive etching (DRIE). Fourth mask 733 (shown in FIG. 7J) may be removed to expose block layer 702.

As shown in FIG. 7L, a fifth mask 740 may be deposited over block layer 702. Fifth mask 740 can be a photoresist mask. Fifth mask 740 can be formed using one or more thin film deposition processes, such as ALD, CVD, PVD, any other suitable processes, or any combination thereof.

With respect to the first group, for one or more first openings 710 from the first set of openings 710 that need to be further extended into stack structure 201, one or more mask openings 742 corresponding to the one or more first openings 710 may be formed in fifth mask 740. By way of examples, a mask opening 742 is formed above mask opening 708 and opening 710 in FIG. 7L.

With respect to the second group, for one or more first openings 720 from the second set of openings 720 that need to be further extended into stack structure 201, one or more mask openings 744 corresponding to the one or more first openings 720 may be formed in fifth mask 740. By way of examples, a mask opening 744 is formed above mask opening 718 and opening 720 in FIG. 7L.

With respect to the third group, for one or more first openings 730 from the second set of openings 730 that need to be further extended into stack structure 201, one or more mask openings 746 corresponding to the one or more first openings 730 may be formed in fifth mask 740. By way of examples, a mask opening 746 is formed above mask opening 728 and opening 730 in FIG. 7L.

With respect to the fourth group, for one or more mask openings 738 from the set of mask openings 738 that need to be further extended into stack structure 201, one or more mask openings 741 corresponding to the one or more mask openings 738 may be formed in fifth mask 740. By way of example, a mask opening 741 is formed above mask opening 738 in FIG. 7L.

As shown in FIG. 7M, using fifth mask 740 (shown in FIG. 7L), stack structure 201 may be etched at one or more first openings 710 from the first set of openings 710 to form one or more second openings 748 extending further into stack structure 201 for the first group. Also using fifth mask 740 (shown in FIG. 7L), stack structure 201 may be etched at one or more first openings 720 from the second set of openings 720 to form one or more second openings 750 extending further into stack structure 201 for the second group. Also using fifth mask 740 (shown in FIG. 7L), stack structure 201 may be etched at one or more first openings 730 from the third set of openings 730 to form one or more second openings 752 extending further into stack structure 201 for the third group. Also using fifth mask 740 (shown in FIG. 7L), stack structure 201 may be etched at one or more mask openings 738 from the set of mask openings 738 to form one or more openings 754 extending further into stack structure 201 for the fourth group. Second openings 748, 750, and 752, and openings 754 can be formed by etching stack structure 201 using fifth mask 740 simultaneously, and may have a same depth. For example, the same depth can be any one of 1 layer, 2 layers, 8 layers, 16 layers, 32 layers, or 64 layers. It is contemplated that the same depth can be any other suitable number of layers, which is not limited herein. Fifth mask 740 may be removed to expose block layer 702, as shown in FIG. 7M.

A first contact hole in the first set of contact holes for the first group may be formed by combining a first one of one or more first openings 710 and a first one of one or more second openings 748. For example, FIG. 7M illustrates that a first contact hole for the first group includes opening 710 and opening 748. A first sidewall shoulder 756 in the first contact hole in the first group is formed at a bottom of opening 710. The first contact hole in the first group is formed by etching stack structure 201 twice using two masks (e.g., mask 703 and mask 740), respectively. When a first contact structure in the first group is formed in the first contact hole (as described below in FIGS. 7N-7Q), the first contact structure may include a first contact shoulder formed on first sidewall shoulder 756. The first contact shoulder may be in the first stack pair. Consistent with some aspects of the present disclosure, the total number of contact shoulders formed in a contact structure is equal to the total number of etching times performed to form the contact hole minus 1 (e.g., the total of contact shoulders=the total number of etching times−1).

A first contact hole in the second set of contact holes for the second group may be formed by combining a first one of one or more first openings 720 and a first one of one or more second openings 750. For example, FIG. 7M illustrates that a first contact hole for the second group includes opening 720 and opening 750. A first sidewall shoulder 758 in the first contact hole in the second group is formed at a bottom of opening 720. The first contact hole in the second group is formed by etching stack structure 201 twice using two masks (e.g., mask 713 and mask 740), respectively. When a first contact structure in the second group is formed in the first contact hole (as described below in FIGS. 7N-7Q), the first contact structure may include a first contact shoulder formed on first sidewall shoulder 758. The contact shoulder may be in the second stack pair.

A first contact hole in the third set of contact holes for the third group may be formed by combining a first one of one or more first openings 730 and a first one of one or more second openings 752. For example, FIG. 7M illustrates that a first contact hole for the third group includes opening 730 and opening 752. A first sidewall shoulder 760 in the first contact hole in the third group is formed at a bottom of opening 730. The first contact hole in the third group is formed by etching stack structure 201 twice using two masks (e.g., mask 723 and mask 740), respectively. When a first contact structure in the third group is formed in the first contact hole (as described below in FIGS. 7N-7Q), the first contact structure may include a first contact shoulder formed on first sidewall shoulder 760. The first contact shoulder may be in the third stack pair.

A first contact hole in the fourth set of contact holes for the fourth group may be formed as a first one of the one or more openings 754. For example, FIG. 7M illustrates that a first contact hole for the fourth group is opening 754. The first contact hole in the fourth group is formed by etching stack structure 201 once using one mask (e.g., mask 740). No sidewall shoulder is formed in the first contact hole in the fourth group. When a first contact structure in the fourth group is formed in the first contact hole (as described below in FIGS. 7N-7Q), the first contact structure may not have any contact shoulder.

It is contemplated that by performing operations like those described above with reference to FIGS. 7L-7M, other contact holes for the first, second, third, and fourth groups can be formed by further etching stack structure 201 using one or more additional masks. For example, a sixth mask (e.g., like fifth mask 740) may be deposited over block layer 702. The sixth mask can be a photoresist mask. With respect to the first group, for a second one of one or more second openings 748 that needs to be further extended into stack structure 201, a mask opening corresponding to the second one of one or more second openings 748 may be formed in the sixth mask. With respect to the second group, for a second one of one or more second openings 750 that needs to be further extended into stack structure 201, a mask opening corresponding to the second one of one or more second opening 750 may be formed in the sixth mask. With respect to the third group, for a second one of one or more second openings 752 that needs to be further extended into stack structure 201, a mask opening corresponding to the second one of one or more second opening 752 may be formed in the sixth mask. With respect to the fourth group, for a second one of one or more openings 754 that needs to be further extended into stack structure 201, a mask opening corresponding to the second one of one or more opening 754 may be formed in the sixth mask.

Then, using the sixth mask, stack structure 201 may be etched at the second one of one or more second openings 748 to form a third opening extending further into stack structure 201 for the first group. Also using the sixth mask, stack structure 201 may be etched at the second one of one or more second openings 750 to form a fourth opening extending further into stack structure 201 for the second group. Also using the sixth mask, stack structure 201 may be etched at the second one of one or more second openings 752 to form a fifth opening extending further into stack structure 201 for the third group. Also using the sixth mask, stack structure 201 may be etched at the second one of one or more openings 754 to form a sixth opening extending further into stack structure 201 for the fourth group. The third opening, the fourth opening, the fifth opening, and the sixth opening can be formed by etching stack structure 201 using the sixth mask simultaneously, and may have a same depth. For example, the same depth can be any remaining one of 1 layer, 2 layers, 8 layers, 16 layers, 32 layers, or 64 layers. Then, the sixth mask may be removed to expose block layer 702.

A second contact hole in the first set of contact holes for the first group may be formed by combining (1) a second one of one or more first openings 710 corresponding to the second one of one or more second openings 748, (2) the second one of one or more second openings 748, and (3) the third opening. For example, the second one of one or more first openings 710 corresponding to the second one of one or more second openings 748 is an opening 710 right above the second one of one or more second openings 748. For the second contact hole in the first group, a first sidewall shoulder 756 is formed at a bottom of the second one of one or more first openings 710, and a second sidewall shoulder is formed at a bottom of the second one of one or more second openings 748. The second contact hole in the first group is formed by etching stack structure 201 three times using three masks (e.g., mask 703, mask 740, and the sixth mask), respectively. When a second contact structure is formed in the second contact hole in the first group (as described below in FIGS. 7N-7Q), the second contact structure may include a first contact shoulder and a second contact shoulder formed on first sidewall shoulder 756 and the second sidewall shoulder, respectively. The first contact shoulder may be in the first stack pair. The second contact shoulder is located below the first stack pair.

A second contact hole in the second set of contact holes for the second group may be formed by combining (1) a second one of one or more first openings 720 corresponding to the second one of one or more second openings 750, (2) the second one of one or more second openings 750, and (3) the fourth opening. For the second contact hole in the second group, a first sidewall shoulder 758 is formed at a bottom of the second one of one or more first openings 720, and a second sidewall shoulder is formed at a bottom of the second one of one or more second openings 750. The second contact hole in the second group is formed by etching stack structure 201 three times using three masks (e.g., mask 713, mask 740, and the sixth mask), respectively. When a second contact structure is formed in the second contact hole in the second group (as described below in FIGS. 7N-7Q), the second contact structure may include a first contact shoulder and a second contact shoulder formed on first sidewall shoulder 758 and the second sidewall shoulder, respectively. The first contact shoulder may be in the second stack pair. The second contact shoulder is located below the second stack pair.

A second contact hole in the third set of contact holes for the third group may be formed by combining (1) a second one of one or more first openings 730 corresponding to the second one of one or more second openings 752, (2) the second one of one or more second openings 752, and (3) the fifth opening. For the second contact hole in the third group, a first sidewall shoulder 760 is formed at a bottom of the second one of one or more first openings 730, and a second sidewall shoulder is formed at a bottom of the second one of one or more second openings 752. The second contact hole in the third group is formed by etching stack structure 201 three times using three masks (e.g., mask 723, mask 740, and the sixth mask), respectively. When a second contact structure is formed in the second contact hole in the third group (as described below in FIGS. 7N-7Q), the second contact structure may include a first contact shoulder and a second contact shoulder formed on first sidewall shoulder 760 and the second sidewall shoulder, respectively. The first contact shoulder may be in the third stack pair. The second contact shoulder is located below the third stack pair.

A second contact hole in the fourth set of contact holes for the fourth group may be formed by combining (1) the second one of one or more openings 754 and (2) the sixth opening. For the second contact hole in the fourth group, a sidewall shoulder is formed at a bottom of the second one of one or more openings 754. The second contact hole in the fourth group is formed by etching stack structure 201 twice times using two masks (e.g., mask 740 and the sixth mask), respectively. When a second contact structure is formed in the second contact hole in the fourth group (as described below in FIGS. 7N-7Q), the second contact structure may include a contact shoulder formed on the sidewall shoulder at the bottom of the second one of one or more openings 754.

As shown in FIG. 7N, block layer 702 (shown in FIG. 7M) is removed. In some implementations, block layer 702 having polysilicon is etched away using KOH. By way of examples, a contact hole 762 for the first group is shown, e.g., contact hole 762 is formed by openings 710 and 748 of FIG. 7M. A contact hole 764 for the second group is shown. For example, contact hole 764 is formed by openings 720 and 750 of FIG. 7M. A contact hole 766 for the third group is shown. For example, contact hole 766 is formed by openings 730 and 752 of FIG. 7M. A contact hole 768 for the fourth group is shown. For example, contact hole 766 is formed by opening 754 of FIG. 7M.

For each contact hole 762, 764, 766, or 768, spacer 202 (e.g., a contact spacer) is formed on a sidewall and a bottom surface of the respective contact hole, thereby covering first dielectric layers 203 and second dielectric layers 205 exposed from the sidewall and bottom surface of the respective contact hole. In some implementations, spacer 202 is formed by depositing dielectric materials, such as silicon oxide, using one or more thin film deposition processes, such as ALD, CVD, PVD, any other suitable processes, or any combination thereof, over the sidewall and the bottom surface of the respective contact hole.

In some implementations, for each contact hole 762, 764, 766, or 768, the part of spacer 202 on the bottom surface of the respective contact hole is removed, for example, by dry etching, to expose part of second dielectric layer 205 in dielectric portion 107 of word line pick-up region 103. In some implementations, the etching rate, direction, and/or duration of RIE are controlled to etch only the part of spacer 202 on the bottom surface, but not on the sidewall, of the respective contact hole, i.e., “punching” through spacer 202 in the z-direction to expose only a corresponding second dielectric layer 205 from the bottom, but not other second dielectric layers 205 from the sidewall.

As illustrated in FIG. 7O, for each contact hole 762, 764, 766, or 768, part of second dielectric layer 205 exposed from the bottom of the respective contact hole is removed by wet etching to form a lateral opening 770, leaving the remainder of second dielectric layer 205 at the same level, as well as other second dielectric layers 205 at other levels, in dielectric portion 107 of word line pick-up region 103 intact. Lateral opening 770 can expose a corresponding conductive layer 302 at the same level in conductive portion 105 of word line pick-up region 103. In some implementations, the part of second dielectric layer 205 is wet etched by applying a wet etchant through the contact hole, creating lateral opening 770 sandwiched between two first dielectric layers 203. The wet etchant can include phosphoric acid for etching second dielectric layer 205 including silicon nitride. In some implementations, the etching rate and/or etching time are controlled to remove only part of second dielectric layer 205 that is enough to expose corresponding conductive layer 302 at the same level in conductive portion 105. By controlling the etching time, the wet etchant does not travel all the way to completely remove second dielectric layer 205 in dielectric portion 107. As a result, dummy channel structures 112 may not need to be formed in dielectric portion 107 of word line pick-up region 103 to provide mechanical support when removing second dielectric layer 205. As illustrated in FIG. 7O, since the sidewall of the respective contact hole is still covered by spacer 202 (e.g., silicon oxide) that is resistant to the etchant for removing second dielectric layers 205 (e.g., silicon nitride), second dielectric layers 205 at other levels remain intact in dielectric portion 107.

In some implementations in which high-k gate dielectric layers 362 are formed surrounding conductive layers 302 (as illustrated in FIG. 3B), once the exposed part of second dielectric layer 205 is etched from the respective contact hole, the corresponding high-k gate dielectric layer 362 surrounding the corresponding conductive layer 302 at the same level is exposed. The exposed part of the corresponding high-k gate dielectric layer 362 can then be etched, for example, using wet etching, to expose the corresponding conductive layer 302 at the same level.

As illustrated in FIG. 7P, for each contact hole 762, 764, 766, or 768, a lateral contact member 206 is formed by depositing a conductive layer through the respective contact hole to fill lateral opening 770. The conductive layer, such as a metal layer, can be deposited using one or more thin film deposition processes, such as ALD, CVD, PVD, any other suitable processes, or any combination thereof. The deposition rate and/or duration may be controlled to ensure that lateral contact member 206 can be in contact with the exposed corresponding conductive layer 302 at the same level as lateral opening 770. In other words, second dielectric layer 205 exposed from the bottom of the respective contact hole can be partially replaced with a corresponding lateral contact member 206 in dielectric portion 107 of word line pick-up region 103, while other second dielectric layers 205 at other levels in dielectric portion 107 remain intact.

For each contact hole 762, 764, 766, or 768, a vertical contact member 204 is formed on the sidewall of the respective contact hole and is in contact with lateral contact member 206. Vertical contact member 204 can be formed in the same process as forming lateral contact member 206 by depositing the conductive layer not only into lateral opening 770, but also on the sidewall and the bottom surface of the respective contact hole, using one or more thin film deposition processes, such as ALD, CVD, PVD, any other suitable processes, or any combination thereof.

As illustrated in FIG. 7Q, for each contact hole 762, 764, 766, or 768 (shown in FIG. 7P), a filler 208 is formed in the respective contact hole to fully or partially fill the respective contact hole. Filler 208, such as a dielectric layer, can be deposited using one or more thin film deposition processes, such as ALD, CVD, PVD, any other suitable processes, or any combination thereof. In some implementations, for each contact hole 762, 764, 766, or 768, a contact pad 210 is formed to cover a corresponding filler 208 and connect to a corresponding vertical contact member 204. Contact pad 210, such as a metal layer, can be deposited using one or more thin film deposition processes, such as ALD, CVD, PVD, any other suitable processes, or any combination thereof. The excess portions of the conductive layer and dielectric layer for forming vertical contact member 204, contact pad 210, and filler 208 can be removed by using chemical mechanical polishing (CMP).

With combined reference to FIGS. 7A-7Q, the contact structures can be divided into 4 groups. For example, the 4 groups can be the 4 groups shown in FIGS. 2D-2E. Masks 703, 713, and 723 (each including a carbon layer and a SiON layer) and block layer 702 can be used to etch stack structure 201 by 384 layers, 256 layers, and 128 layers to form openings 710, 720, and 730, respectively. Mask 733 can be used to etch block layer 702 to form mask opening 738. Then, up to 127 additional layers (e.g., 64+32+16+8+4+2+1=127) can be etched in stack structure 201 from openings 710, 720, 730, and 738 using 7 additional masks (e.g., including mask 740). For example, a first additional mask (e.g., mask 740) may be used to further etch stack structure 201 by 64 layers; a second additional mask may be used to further etch stack structure 201 by 32 layers; a third additional mask may be used to further etch stack structure 201 by 16 layers; a fourth additional mask may be used to further etch stack structure 201 by 8 layers; a fifth additional mask may be used to further etch stack structure 201 by 4 layers; a sixth additional mask may be used to further etch stack structure 201 by 2 layers; and a seventh additional mask may be used to further etch stack structure 201 by 1 layer. As a result, respective contact holes for the 4 groups are formed. Each contact hole can be formed by up to 8 etchings. Then, the contact structures can be formed in the respective contact holes. By using block layer 702, overlay shift can be avoided, and CDs of the contact structures formed in the contact holes can be reduced. Etching defects such as over etching or under etching can be reduced or eliminated.

FIG. 8 illustrates different numbers of layers to be etched using different masks, according to some aspects of the present disclosure. For ten masks, Table 2 lists the respective number of layers etched in stack structure 201 (e.g., the number of ET layers) using each mask theoretically. For example, for an n^{th} mask (n=1, 2, . . . , 10), the number of layers etched using the n^{th} mask can be 2ⁿ⁻¹. Then, the total number of etched layers for the 1^{st} to n^{th} masks (n masks in total) can be up to 2ⁿ−1.

For 15 masks, Table 3 lists the respective number of etched layers using each mask in some cases. For example, for an n^{th} mask (n=1, 2, 3, 4, 5, 6, 7), the number of layers etched using the n^{th} mask can be 2ⁿ⁻¹. However, for an n^{th} mask (n=8, 9, . . . , 15), the number of layers etched using the n^{th} mask is much less than 2ⁿ⁻¹. For example, for n>7, the number of layers etched using the n^{th} mask is at most 60 layers. As a result, more masks (e.g., more than n masks) are needed to achieve the total etched layers of 2ⁿ−1 when n>7. For example, to etch a total number of 507 layers, 15 masks are needed.

For 11 masks, Table 4 lists the respective number of etched layers using each mask in the solution disclosed herein. For example, with reference to FIGS. 7A-7Q, first mask 703 (e.g., Mask 1 in Table 4) is used to etch 384 layers in stack structure 201 to form opening 710 of FIG. 7C; second mask 713 (e.g., Mask 2 in Table 4) is used to etch 256 layers in stack structure 201 to form opening 720 of FIG. 7F; third mask 723 (e.g., Mask 3 in Table 4) is used to etch 128 layers in stack structure 201 to form opening 730 of FIG. 7I; fourth mask 733 (e.g., Mask 4 in Table 4) is used to etch block layer 702 (denoted as HM ET in Table 4) to form mask opening 738 of FIG. 7K; and fifth mask 740 (e.g., Mask 5 in Table 4) is used to further etch 64 layers from one or more of openings 710, 720, and 730, and opening 738, as shown in FIGS. 7N-7M. To etch a total number of 511 layers, only 11 masks are needed, which is less than the number of masks needed in Table 3. By reducing the number of etchings times and the number of masks used to form the contact structures, the fabrication process can be simplified, and CDs of the contact structures can be reduced.

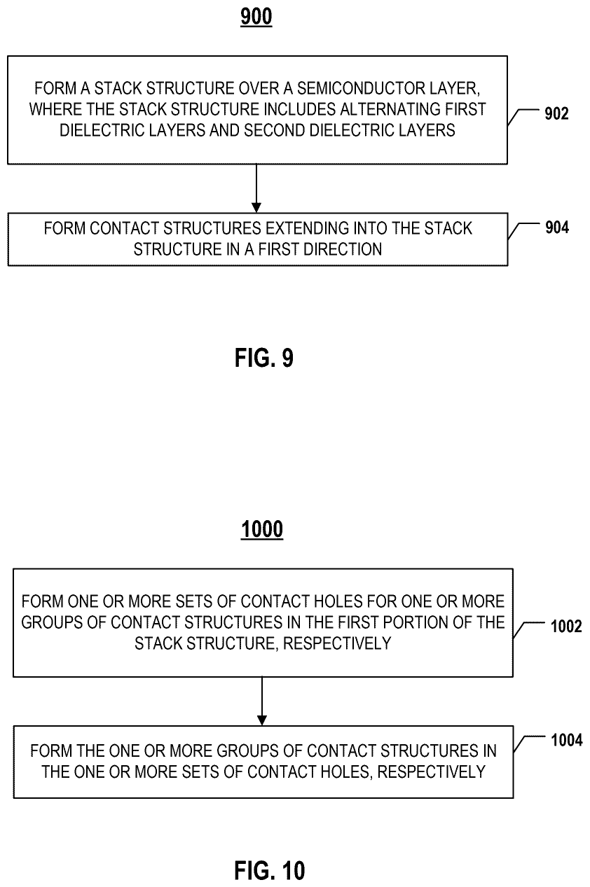

FIG. 9 is a flowchart of another method 900 for forming a 3D memory device having contact structures, according to some aspects of the present disclosure. The 3D memory device can be memory device 100 or any other memory device disclosed herein. It is understood that the operations shown in method 900 are not exhaustive and that other operations can be performed as well before, after, or between any of the illustrated operations. Further, some of the operations may be performed simultaneously, or in a different order than shown in FIG. 9.

Referring to FIG. 9, method 900 starts at operation 902, in which a stack structure is formed over a semiconductor layer. The stack structure includes alternating first dielectric layers and second dielectric layers. For example, stack structure 201 can be formed by performing operations like those described above with reference to FIG. 5A.

Method 900 proceeds to operation 904, as illustrated in FIG. 9, in which contact structures extending into the stack structure in a first direction are formed. A method for forming the stack structures is illustrated below with reference to FIG. 10. For example, contact structures 106 may be formed by performing operations like those described above with reference to FIG. 7A-7Q, and the similar description will not be repeated herein.

FIG. 10 is a flowchart of a method 1000 for forming contact structures in a stack structure, according to some aspects of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10.

In some implementations, the contact structures may be divided into one or more groups based on contact depths of the contact structures in a first direction. Referring to FIG. 10, method 1000 starts at operation 1002, in which one or more sets of contact holes are formed for the one or more groups of contact structures in a first portion of the stack structure, respectively. Each group of contact structures may include at least a subset of the contact structures.

Method 1000 proceeds to operation 1004, as illustrated in FIG. 10, in which the one or more groups of contact structures are formed in the one or more sets of contact holes, respectively. For example, a first group of contact structures may be formed in a first set of contact hole. A second group of contact structures may be formed in a second set of contact holes.

In some implementations, at operation 1002, method 1000 may include forming the first set of contact holes for the first group. Specifically, forming the first set of contact holes may include: forming a block layer on the stack structure; and etching the block layer and the stack structure with a first mask to form a first set of openings for the first group in the stack structure. The first set of openings have a first depth in the first direction, and bottoms of the first set of openings are in the first stack pair. For example, as described above with reference to FIGS. 7A-7C, the first set of openings 710 may be formed by etching block layer 702 and stack structure 201 using first mask 703. The first set of openings 710 have first depth 709 in the z-direction, and bottoms of the first set of openings 710 are in the first stack pair including first dielectric layer 203A and second dielectric layer 205A.

In some implementations, forming the first set of contact holes may further include using a second mask to etch the stack structure at one or more first openings from the first set of openings to form one or more second openings extending further into the stack structure. The first set of contact holes may include a first contact hole including a first one of the one or more first openings and a first one of the one or more second openings. A first sidewall shoulder is formed at a bottom of the first one of the one or more first openings. For example, as described above with reference to FIG. 7M, an opening 748 may be formed to further extend into stack structure 201 at opening 710 using mask 740 (shown in FIG. 7L). The first contact hole in the first group may be formed by openings 710 and 748. A sidewall shoulder 756 is formed at a bottom of opening 710.

In some implementations, the stack structure may include a first portion and a second portion adjacent to the first portion. The contact structures extend into the first portion of the stack structure. Method 1000 may further include performing a gate line replacement process to replace parts of the second dielectric layers in the second portion of the stack structure with conductive layers. The contact structures extend into the first portion of the stack structure and connect to corresponding conductive layers from the conductive layers, respectively. For example, operations like those described above with reference to FIGS. 5D-5I can be performed to conduct the gate line replacement process. As shown in FIG. 5J, contact structures 106 formed thereof extend into dielectric portion 107 of word line pick-up region 103 and connect to corresponding conductive layers 302, respectively.

In some implementations, the first group may include a first subset of the contact structures associated with a first subset of contact depths in a first depth range. The first subset of the contact structures in the first group may include a first contact structure including a spacer, a vertical contact member, and a lateral contact member. At operation 1004, method 1000 may include forming the first subset of the contact structures in the first set of contact holes, respectively. Specifically, forming the first subset of the contact structures in the first set of contact holes, respectively, may include forming the first contact structure in the first contact hole, which includes forming the spacer on a sidewall of the first contact hole; and forming the lateral contact member below a bottom of the first contact hole and forming the vertical contact member on a sidewall of the spacer to connect to the lateral contact member. The lateral contact member connects to a corresponding one of the conductive layers. For example, operations like those described above with reference FIGS. 7N-7Q can be performed to form the first contact structure.

In some implementations, the vertical contact member may include a first vertical-contact segment, a first contact shoulder from the first set of contact shoulders, and a second vertical-contact segment. The first contact shoulder connects to the first vertical-contact segment and the second vertical-contact segment. The spacer may include a first spacer segment, a spacer shoulder, and a second spacer segment. The spacer shoulder connects to the first spacer segment and the second spacer segment, and is in the first stack pair. The spacer shoulder is formed on the first sidewall shoulder, and the first contact shoulder is formed on the spacer shoulder. For example, with reference to FIG. 7P, a spacer shoulder 221 is formed on sidewall shoulder 756, and contact shoulder 212 is formed on spacer shoulder 221.

In some implementations, the second group may include a second subset of the contact structures associated with a second subset of contact depths in a second depth range. The second depth range is different from the first depth range. At operation 1002, method 1000 may further include forming a second set of contact holes for the second group in the stack structure; and at operation 1004, method 1000 may further include forming the second subset of the contact structures in the second set of contact holes, respectively. The second subset of the contact structures in the second group may include a second set of contact shoulders located in a second stack pair. The second stack pair includes a second one of the first dielectric layers and a second one of the second dielectric layers, and is different from the first stack pair.

In some implementations, forming the second set of contact holes may include etching the block layer and the stack structure with a third mask to form a second set of openings in the stack structure. The second set of openings have a second depth in the first direction, and bottoms of the second set of openings are in the second stack pair. For example, with reference to FIGS. 7D-7F, openings 720 may be formed by etching block layer 702 and stack structure 201 using mask 713. Openings 720 may have second depth 722, and bottoms of openings 720 are in the second stack pair including first dielectric layer 203B and second dielectric layer 205B.

Forming the second set of contact holes further includes: during formation of the one or more second openings, using the second mask to etch the stack structure at one or more third openings from the second set of openings to form one or more fourth openings extending further into the stack structure. The second set of contact holes may include a second contact hole including (i) a first one of the one or more third openings and (ii) a first one of the one or more fourth openings. A second sidewall shoulder is formed at a bottom of the first one of the one or more third openings.

For example, with reference to FIGS. 7L-7M, during formation of opening 748, mask 740 is also used to etch stack structure 201 at opening 720 to form opening 750 extending further into stack structure 201. A second contact hole in the second group may include (i) opening 720 and (ii) opening 750. A sidewall shoulder 758 is formed at a bottom of opening 720.

In some implementations, forming the first set of contact holes may further include using a fourth mask to etch the stack structure at a second one of the one or more second openings to form a fifth opening extending further into the stack structure. Forming the second set of contact holes may further include using the fourth mask to etch the stack structure at a second one of the one or more fourth openings to form a sixth opening extending further into the stack structure. The first set of contact holes may include a third contact hole including (1) a second one of the one or more first openings corresponding to the second one of the one or more second openings, (2) the second one of the one or more second openings, and (3) the fifth opening. A third sidewall shoulder is formed at a bottom of the second one of the one or more second openings. The second set of contact holes may include a fourth contact hole including (1) a second one of the one or more third openings corresponding to the second one of the one or more fourth openings, (2) the second one of the one or more fourth openings, and (3) the sixth opening. A fourth sidewall shoulder is formed at a bottom of the second one of the one or more fourth openings.

In some implementations, the first subset of the contact structures in the first group may include a third contact structure formed in the third contact hole. The third contact structure may include (1) a first contact shoulder from the first set of contact shoulders and formed on a first sidewall shoulder; and (2) a second contact shoulder formed on the third sidewall shoulder. A depth of the second contact shoulder in the first direction is greater than a depth of the first contact shoulder in the first direction.

In some implementations, the third contact structure further includes a contact pad. The depth of the second contact shoulder in the first direction is a distance from the contact pad to the second contact shoulder in the first direction. The depth of the first contact shoulder in the first direction is a distance from the contact pad to the first contact shoulder in the first direction.

In some implementations, forming the second set of contact holes further includes etching the block layer with a fifth mask to form a set of mask openings; and using the second mask to etch the stack structure at a mask opening from the set of mask openings to form a seventh opening extending into the stack structure. The second set of contact holes may include a sixth contact hole including the seventh opening. For example, with reference to FIGS. 7J-7M, mask 733 may be used to etch block layer 702 to form mask opening 738. Mask 740 may be used to etch stack structure 201 at mask opening 738 to form opening 754, while mask 740 is also used to etch stack structure 201 at opening 710 to form opening 748 for the first group. Then, a contact hole formed thereof may include opening 754.

In some implementations, one of the contact structures is formed in a contact hole, and the contact hole may include a plurality of openings formed by etching the stack structure with a plurality of etching times. The total number of contact shoulders formed in the contact structure can be equal to the total number of the plurality of etching times minus 1 (e.g., the number of contact shoulders=the number of etching times−1).

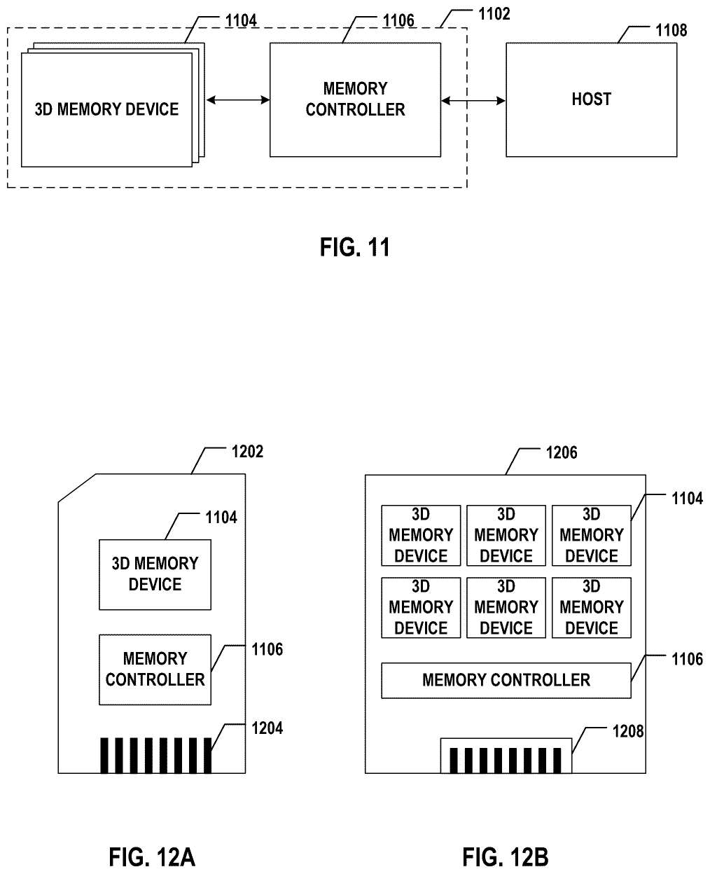

FIG. 11 illustrates a block diagram of an exemplary system 1100 having a 3D memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1108 and a memory system 1102 having one or more 3D memory devices 1104 and a memory controller 1106. Host 1108 can be a processor of an electronic device, such as a central processing unit (CPU), or a system-on-chip (SoC), such as an application processor (AP). Host 1108 can be configured to send or receive data to or from 3D memory devices 1104.

3D memory device 1104 can be any 3D memory device disclosed herein, such as 3D memory device 100 depicted in FIGS. 1, 2A-2E, and 3A-3B. In some implementations, each 3D memory device 1104 includes a NAND Flash memory. Consistent with the scope of the present disclosure, contact structures can replace the staircase structures and word line contacts to achieve word line pick-up/fan-out functions, thereby reducing the manufacturing cost and simplifying the fabrication process.

Memory controller 1106 (a.k.a., a controller circuit) is coupled to 3D memory device 1104 and host 1108 and is configured to control 3D memory device 1104, according to some implementations. For example, memory controller 1106 may be configured to operate the plurality of channel structures via the word lines. Memory controller 1106 can manage the data stored in 3D memory device 1104 and communicate with host 1108. In some implementations, memory controller 1106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1106 can be configured to control operations of 3D memory device 1104, such as read, erase, and program operations. Memory controller 1106 can also be configured to manage various functions with respect to the data stored or to be stored in 3D memory device 1104 including, but not limited to bad-block management, garbage collection, logical-to-physical address conversion, wear leveling, etc. In some implementations, memory controller 1106 is further configured to process error correction codes (ECCs) with respect to the data read from or written to 3D memory device 1104. Any other suitable functions may be performed by memory controller 1106 as well, for example, formatting 3D memory device 1104. Memory controller 1106 can communicate with an external device (e.g., host 1108) according to a particular communication protocol. For example, memory controller 1106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1106 and one or more 3D memory devices 1104 can be integrated into various types of storage devices, for example, be included in the same package, such as a universal Flash storage (UFS) package or an eMMC package. That is, memory system 1102 can be implemented and packaged into different types of end electronic products. In one example as shown in FIG. 12A, memory controller 1106 and a single 3D memory device 1104 may be integrated into a memory card 1202. Memory card 1202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1202 can further include a memory card connector 1204 electrically coupling memory card 1202 with a host (e.g., host 1108 in FIG. 11). In another example as shown in FIG. 12B, memory controller 1106 and multiple 3D memory devices 1104 may be integrated into an SSD 1206. SSD 1206 can further include an SSD connector 1208 electrically coupling SSD 1206 with a host (e.g., host 1108 in FIG. 11). In some implementations, the storage capacity and/or the operation speed of SSD 1206 is greater than those of memory card 1202.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a stack structure comprising alternating first layers and first dielectric layers, wherein the first layers in a first portion of the stack structure comprise second dielectric layers, and the first layers in a second portion adjacent to the first portion of the stack structure comprise conductive layers; and
contact structures extending into the first portion of the stack structure in a first direction and connecting to corresponding conductive layers from the conductive layers, respectively,
wherein the contact structures are divided into one or more groups based on contact depths of the contact structures in the first direction,
wherein the one or more groups comprise a first group including at least a first subset of the contact structures associated with a first subset of the contact depths in a first depth range, and
wherein the first subset of the contact structures in the first group comprise a first set of contact shoulders located in a first stack pair, and the first stack pair comprises a first one of the first dielectric layers and a first one of the second dielectric layers.

2. The memory device of claim 1, wherein the first subset of the contact structures in the first group comprise a first contact structure, and the first contact structure comprises:
a vertical contact member and a lateral contact member connecting to the vertical contact member, wherein the vertical contact member extends in the first direction, and the lateral contact member connects to one of the corresponding conductive layers.

3. The memory device of claim 2, wherein the vertical contact member comprises:
a first vertical-contact segment, a first contact shoulder from the first set of contact shoulders, and a second vertical-contact segment, wherein the first contact shoulder connects to the first vertical-contact segment and the second vertical-contact segment.

4. The memory device of claim 3, wherein in a second direction perpendicular to the first direction, a size of an end of the first vertical-contact segment that connects to the first contact shoulder is greater than a size of an end of the second vertical-contact segment which also connects to the first contact shoulder.

5. The memory device of claim 3, wherein the vertical contact member of the first contact structure further comprises:
a second contact shoulder located within the first depth range, wherein the second contact shoulder connects to the second vertical-contact segment, and a depth of the second contact shoulder in the first direction is greater than a depth of the first contact shoulder in the first direction.

6. The memory device of claim 5, wherein the vertical contact member further comprises:
a third vertical-contact segment, wherein the second contact shoulder connects to the second vertical-contact segment and the third vertical-contact segment.

7. The memory device of claim 3, wherein:
the first vertical-contact segment has a bowing shape in a cross-sectional view in a plane determined by the first direction and a second direction perpendicular to the first direction;
the first vertical-contact segment has a first end connected to the first contact shoulder and a second end away from the first contact shoulder; and
in the second direction, a size of the first end of the first vertical-contact segment and a size of the second end of the first vertical-contact segment are smaller than a size of the first vertical-contact segment between the first end and the second end in the second direction.

8. The memory device of claim 5, wherein the first contact structure further comprises:
a spacer surrounding the vertical contact member;
a filler surrounded by the vertical contact member; and
a contact pad covering the filler and connected to the vertical contact member.

9. The memory device of claim 8, wherein:
the depth of the second contact shoulder in the first direction is a distance from the contact pad to the second contact shoulder in the first direction; and
the depth of the first contact shoulder in the first direction is a distance from the contact pad to the first contact shoulder in the first direction.

10. The memory device of claim 8, wherein the spacer comprises:
a first spacer segment, a spacer shoulder, and a second spacer segment, wherein the spacer shoulder connects to the first spacer segment and the second spacer segment, and is located in the first stack pair.

11. The memory device of claim 10, wherein the first spacer segment has a bowing shape in a cross-sectional view in a plane determined by the first direction and a second direction perpendicular to the first direction.

12. The memory device of claim 1, wherein the one or more groups further comprise:
a second group including a second subset of the contact structures associated with a second subset of the contact depths in a second depth range, wherein the second depth range is different from the first depth range,
wherein the second subset of the contact structures in the second group comprise:
a second set of contact shoulders located in a second stack pair comprising a second one of the first dielectric layers and a second one of the second dielectric layers, wherein the second stack pair is different from the first stack pair.

13. The memory device of claim 1, wherein:
the second portion of the stack structure comprises a first sub-portion and a second sub-portion separated from the first sub-portion, and the first portion of the stack structure is between and connects to the first sub-portion and the second sub-portion; or
the first portion of the stack structure comprises a third sub-portion and a fourth sub-portion separated from the third sub-portion, and the second portion of the stack structure is between and connects to the third sub-portion and the fourth sub-portion.

14. The memory device of claim 1, further comprising a peripheral circuit connected to the contact structures, wherein the peripheral circuit comprises a device layer including transistors, and the contact structures connect to the device layer.

15. A memory device, comprising:
a stack structure comprising alternating first layers and first dielectric layers, wherein the first layers in a first portion of the stack structure comprise second dielectric layers, and the first layers in a second portion adjacent to the first portion of the stack structure comprise conductive layers;
a first group of contact structures extending into the first portion of the stack structure in a first direction and connecting to a first subset of the conductive layers, respectively, wherein the first group of contact structures have first contact depths in a first depth range, respectively, and comprise a first set of contact shoulders located in a first stack pair; and
a second group of contact structures extending into the first portion of the stack structure in the first direction and connecting to a second subset of the conductive layers, respectively, wherein the second group of contact structures have second contact depths in a second depth range, respectively, and comprise a second set of contact shoulders located in a second stack pair different from the first stack pair.

16. A method for forming a memory device, comprising:
forming a stack structure comprising alternating first dielectric layers and second dielectric layers; and
forming contact structures extending into the stack structure in a first direction,
wherein the contact structures are divided into one or more groups based on contact depths of the contact structures in the first direction,
wherein the one or more groups comprise a first group including at least a first subset of the contact structures associated with a first subset of the contact depths in a first depth range, and
wherein the first subset of the contact structures comprise a first set of contact shoulders located in a first stack pair, and the first stack pair comprises a first one of the first dielectric layers and a first one of the second dielectric layers.

17. The method of claim 16, wherein forming the contact structures comprises:
forming a first set of contact holes for the first group in the stack structure; and
forming the first subset of the contact structures in the first set of contact holes, respectively.

18. The method of claim 17, wherein forming the first set of contact holes comprises:
forming a block layer on the stack structure; and
etching the block layer and the stack structure with a first mask to form a first set of openings for the first group in the stack structure, wherein the first set of openings have a first depth in the first direction, and bottoms of the first set of openings are in the first stack pair.

19. The method of claim 18, wherein forming the first set of contact holes further comprises:
using a second mask to etch the stack structure at one or more first openings from the first set of openings to form one or more second openings extending further into the stack structure,
wherein the first set of contact holes comprise a first contact hole comprising a first one of the one or more first openings and a first one of the one or more second openings.

20. The method of claim 19, wherein the stack structure comprises a first portion and a second portion adjacent to the first portion, the contact structures extend into the first portion of the stack structure, and the method further comprises:
performing a gate line replacement process to replace parts of the second dielectric layers in the second portion of the stack structure with conductive layers,
wherein the contact structures extend into the first portion of the stack structure and connect to corresponding conductive layers from the conductive layers, respectively.
